(19) United States
(12) Patent Application Publication
(10) Pub. No.: US 2025/0221030 A1
(43) Pub. Date: Jul. 3, 2025

(54) STACKED FORKSHEET TRANSISTORS

(71) Applicant: International Business Machines Corporation, Armonk, NY (US)

(72) Inventors: Abir Shadman, Albany, NY (US); Shay Reboh, Guilderland, NY (US); Albert M. Chu, Nashua, NH (US); Ruilong Xie, Niskayuna, NY (US); Julien Frougier, Albany, NY (US)

(21) Appl. No.: 18/399,017

(22) Filed: Dec. 28, 2023

(51) Int. Cl. H01L 27/092; H01L 21/822; H01L 21/8238; H01L 23/528; H01L 29/06; H01L 29/423; H01L 29/66; H01L 29/775; H01L 29/786

(52) U.S. Cl. CPC H10D 84/856; H01L 23/528; H10D 30/014; H10D 30/031; H10D 30/43; H10D 30/6735; H10D 30/6757; H10D 62/121; H10D 64/017; H10D 84/0186; H10D 84/038; H10D 88/01

(57) ABSTRACT

Semiconductor structures including stacked transistors are provided. The semiconductor structures can include a pair of stacked forksheet transistors that have a shared second (top) gate electrode, or the structures can include a pair of stacked forksheet transistors that have non-shared second (top) gate electrodes. In either of these embodiments, the second (top) gate electrode is separated from a first (bottom) gate electrode by a frontside gate cut structure.

### BACKGROUND

The present application relates to semiconductor technology, and more particularly to a semiconductor structure including a pair of stacked transistors that are separated by a dielectric wall structure.

A forksheet transistor is a type of transistor that is being currently developed for 2 nm nodes and beyond. The stacked forksheet transistor is an extension of vertically stacked nanosheet transistors, where the nanosheets are controlled by a tri-gate forked structure, which is achieved by introducing a dielectric wall structure between the p-type field effect transistor FET (i.e., PFET) and the n-type FET (i.e., NFET). This isolation allows for tighter n-to-p spacing and higher performance. In forksheet devices, both the NFET and PFET are integrated in the same structure, unlike existing gate-all-around FETs that use different devices for the NFETs and PFETs. In a stacked forksheet FET configuration, one forksheet FET is stacked on top of another forksheet FET. Stacked forksheet FETs have improved circuit density and performance.

### SUMMARY

Semiconductor structures including stacked transistors are provided. The semiconductor structures can include a pair of stacked forksheet transistors that have a shared second (top) gate electrode, or the structures can include a pair of stacked forksheet transistors that have non-shared second (top) gate electrodes. In either of these embodiments, the second (top) gate electrode is separated from a first (bottom) gate electrode by a frontside gate cut structure.

In some embodiments of the present application, the semiconductor structure includes a dielectric wall structure directly contacting and physically separating a first stacked transistor from a second stacked transistor; a merged top gate electrode extending over the dielectric wall structure and surrounding a top semiconductor channel region of the first stacked transistor and a top semiconductor channel region of the second stacked transistor; a bottom gate electrode of the first stacked transistor surrounding a bottom semiconductor channel region of the first stacked transistor; a bottom gate electrode of the second stacked transistor surrounding a bottom semiconductor channel region of the second stacked transistor; a first frontside bottom gate contact structure contacting the bottom gate electrode of the first stacked transistor; a second frontside bottom gate contact structure contacting the bottom gate electrode of the second stacked transistor; and a frontside back-end-of-the-line (BEOL) interconnect structure located over the first stacked transistor and the second stacked transistor and in electrical contact with the first frontside bottom gate contact structure and the second frontside bottom gate contact structure.

In other embodiments of the present application, the semiconductor structure includes a dielectric wall structure directly contacting and physically separating a first stacked transistor from a second stacked transistor; a merged top gate electrode extending over the dielectric wall structure and surrounding a top semiconductor channel region of the first stacked transistor and a top semiconductor channel region of the second stacked transistor; a bottom gate electrode pf the first stacked transistor surrounding a bottom semiconductor channel region of the first stacked transistor; a bottom gate electrode of the second stacked transistor surrounding a bottom semiconductor channel region of the second stacked transistor; a first backside bottom gate contact structure contacting the bottom gate electrode of the first stacked transistor; a second backside bottom gate contact structure contacting the bottom gate electrode of the second stacked transistor; and a backside interconnect structure located beneath the first stacked transistor and the second stacked transistor and in electrically contact with the first backside bottom gate contact structure and the second backside bottom gate contact structure.

In yet other embodiments of the present application, the semiconductor structure includes a dielectric wall structure directly contacting and physically separating a first stacked transistor from a second stacked transistor; a first top gate electrode located on a first side the dielectric wall structure and surrounding a top semiconductor channel region of the first stacked transistor; a second top gate electrode located on a second side the dielectric wall structure and surrounding a top semiconductor channel region of the second stacked transistor; a first bottom gate electrode surrounding a bottom semiconductor channel region of the first stacked transistor; a second bottom gate electrode surrounding a bottom semiconductor channel region of the second stacked transistor; a first non-shared backside bottom gate contact structure contacting the first bottom gate electrode of the first stacked transistor; a second non-shared backside bottom gate contact structure contacting the second bottom gate electrode of the second stacked transistor; and a frontside BEOL interconnect structure located over the first stacked transistor and the second stacked transistor and in electrical contact with the first non-shared frontside bottom gate contact structure and the second non-shared frontside bottom gate contact structure.

### BRIEF DESCRIPTION OF THE DRAWINGS

FIG. 1 is a cross sectional view of an exemplary semiconductor structure that can be employed in the present application, the exemplary semiconductor structure includes a substrate, a first nanosheet stack of alternating first sacrificial semiconductor material nanosheets and first semiconductor channel material nanosheets, a middle dielectric isolation layer, and a second nanosheet stack of alternating second sacrificial semiconductor material nanosheets and second semiconductor channel material nanosheets, wherein the first nanosheet stack and the middle dielectric isolation layer have a first width and the second nanosheet stack has a second width that is less than the first width, and wherein a sidewall of each of the first nanosheet stack, the middle dielectric isolation layer, and the second nanosheet stack is in direct physical contact with a sidewall of a dielectric wall structure.

FIG. 2 is a cross sectional view of the exemplary semiconductor structure shown in FIG. 1 after forming a patterned mask that reveals an area in which a neighboring pair of first and second nanosheet stacks are spaced apart by one of the dielectric wall structures.

FIG. 3 is a cross sectional view of the exemplary semiconductor structure shown in FIG. 2 after revealing the neighboring pair of first and second nanosheet stacks and the dielectric wall structure that are not protected by the patterned mask.

FIG. 4 is a cross sectional view of the exemplary semiconductor structure shown in FIG. 3 after reducing the height of the revealed dielectric wall structure and removing the patterned mask.

FIG. 5 is a cross sectional view of the exemplary semiconductor structure shown in FIG. 4 after forming a sacrificial gate material.

FIG. 6 is a cross sectional view of the exemplary semiconductor structure shown in FIG. 5 after forming inner spacers, removing the sacrificial gate material, and suspending each first semiconductor channel material nanosheet of the first nanosheet stack and each second semiconductor channel material nanosheet of the second nanosheet stack.

FIG. 7 is a cross sectional view of the exemplary semiconductor structure shown in FIG. 6 after forming a first gate structure wrapping around and along a physically exposed sidewall of each first semiconductor channel material nanosheet of the first nanosheet stack, the middle dielectric isolation layer and each second semiconductor channel material nanosheet of the second nanosheet stack, the first gate structure including a first gate dielectric layer and a first gate electrode.

FIG. 8 is a cross sectional view of the exemplary semiconductor structure shown in FIG. 7 after forming a frontside gate cut structure.

FIG. 9 is a cross sectional view of the exemplary semiconductor structure shown in FIG. 8 after removing the first gate electrode that is in contact with each second semiconductor channel material nanosheet of the second nanosheet stack.

FIG. 10 is a cross sectional view of the exemplary semiconductor structure shown in FIG. 9 after forming a second gate electrode in contact with each second semiconductor channel material nanosheet of the second nanosheet stack, and forming frontside contact structures.

FIG. 11 is a cross sectional view of the exemplary semiconductor structure shown in FIG. 10 after forming a middle-of-the-line (MOL) dielectric layer and a frontside back-end-of-the-line (BEOL) interconnect structure, wherein the MOL dielectric layer includes MOL contact structures embedded therein.

FIG. 12 is a cross sectional view of the exemplary semiconductor structure shown in FIG. 11 after forming a carrier wafer on the frontside BEOL interconnect structure, and removing a first semiconductor layer of the substrate.

FIG. 13 is a cross sectional view of the exemplary semiconductor structure shown in FIG. 12 after removing an etch stop layer of the substrate, forming a backside gate cut structure and a backside interconnect structure.

FIGS. 14-19 are cross sectional view illustrating other exemplary semiconductor structures that can be provided by the present application; these other exemplary semiconductor structures include another backside processing embodiment as shown in FIG. 14, and non-backside processing embodiments as shown in FIGS. 15-19.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in width, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In stacked nanosheet and stacked forksheet technology, the top and bottom stacks typically have transistors of opposite polarity. The transistors have multiple semiconductor channel material nanosheets stacked vertically. For some cases, it is needed to have the gate contacts to certain number of semiconductor channel material nanosheets either in the top or bottom tier. The gate contact to the required number of nanosheet transistors can vary depending on the application. Also, independent contact and merged contact to both tiers are needed for some circuit designs. However, there is a lack of a viable embedded contact scheme for the semiconductor hardware at the MOL level.

In the present application, a semiconductor structure is described and illustrated as containing a stacked forksheet transistor. A transistor (or FET)) includes a source region, a drain region, a semiconductor channel region located between the source region and the drain region, and a gate structure located above the semiconductor channel region. The source region and the drain region can be referred to as a source/drain region. A forksheet FET is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. Each semiconductor channel material nanosheet has a sidewall that in in direct physical contact with a dielectric wall structure. The gate structure includes a gate dielectric and a gate electrode. The gate structure wraps contacts three surfaces (top and bottom and another sidewall) of each of the spaced apart semiconductor channel material nanosheets. In a stacked FET, one forksheet FET is stacked above another forksheet FET.

In the present application, the semiconductor structure includes a frontside and a backside. The frontside includes a side of the structure that includes the stacked forksheet FET, frontside contact structures, and a frontside BEOL structure. The backside of the semiconductor structure is the side of the structure that is opposite the frontside. The backside typically includes at least a backside interconnect structure.

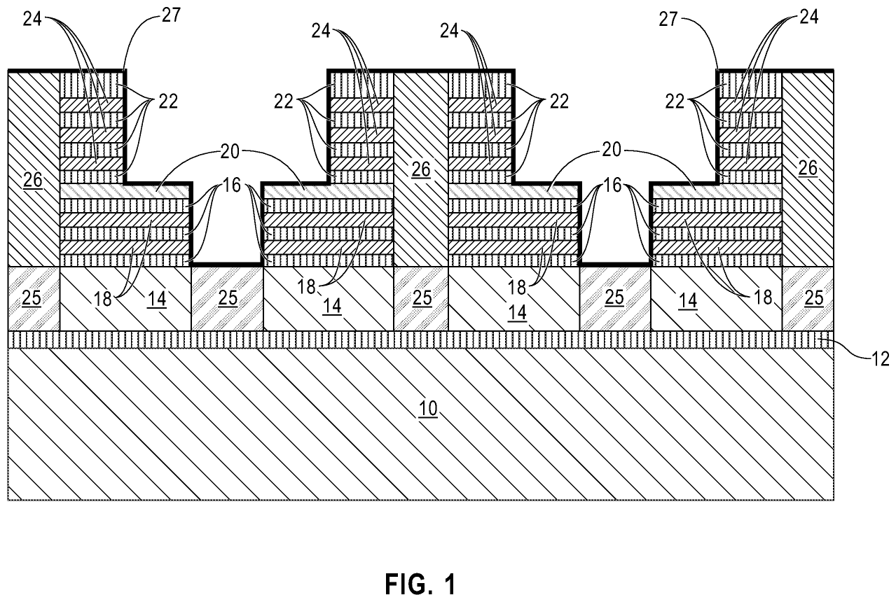

Reference is first made to FIG. 1, which is a cross sectional view of an exemplary semiconductor structure that can be employed in the present application. The exemplary semiconductor structure includes a substrate, a first nanosheet stack of alternating first sacrificial semiconductor material nanosheets 16 and first semiconductor channel material nanosheets 18, a middle dielectric isolation layer 20, and a second nanosheet stack of alternating second sacrificial semiconductor material nanosheets 22 and second semiconductor channel material nanosheets 24. In the present application, the second nanosheet stack is located above the first nanosheet stack. Thus, the region including the first nanosheet stack is a first (or bottom) device region, and the region including the second nanosheet stack is a second (or top) device region. In the present application, a plurality of first nanosheet stacks, middle dielectric isolation layers 20, and second nanosheet stacks are shown. Please note that this cross sectional view of the channel region, and the source/drain regions are not shown. In the illustrated drawings. the current would flow into and out of the page of the drawing from the source region into the channel region than into the drain region.

As is illustrated in FIG. 1, the first nanosheet stack (including the first sacrificial semiconductor material nanosheets 16 and the first semiconductor channel material nanosheets 18) and the middle dielectric isolation layer 20 has a first width, and the second nanosheet stack (including the sacrificial semiconductor material nanosheets 22 and the second semiconductor channel material nanosheets 24) has a second width that is less than the first width. In the present application, a sidewall (i.e., hereinafter a first sidewall) of each of the first nanosheet stack (including the first sacrificial semiconductor material nanosheets 16 and the first semiconductor channel material nanosheets 18), the middle dielectric isolation layer 20 and the second nanosheet stack (including the sacrificial semiconductor material nanosheets 22 and the second semiconductor channel material nanosheets 24) is in direct physical contact with a sidewall of a dielectric wall structure 26. In the present application, at least one of the dielectric wall structures 26 isolates a neighboring pair of first nanosheet stack, middle dielectric isolation layer 20, and second nanosheet stack from a neighboring first nanosheet stack, middle dielectric isolation layer 20, and second nanosheet stack.

In some embodiments of the present application and as is illustrated in FIG. 1, shallow trench isolation structures 25 can be present in the substrate. In other embodiments (not shown), the shallow trench isolation structures 25 can be omitted from the exemplary structure illustrated in FIG. 1. In embodiments in which the shallow trench isolation structures 25 are present, each dielectric wall structure 26 can land on a surface of an underlying shallow trench isolation structure 25. Each shallow trench isolation structure 25 can be used to define different active areas of the exemplary structure.

The illustrated semiconductor structure shown in FIG. 1 also includes a dielectric liner 27. Dielectric liner 27 is located on a sidewall (i.e., hereinafter a second sidewall) of each of the first nanosheet stack (including the first sacrificial semiconductor material nanosheets 16 and the first semiconductor channel material nanosheets 18), the middle dielectric isolation layer 20 and the second nanosheet stack (including the sacrificial semiconductor material nanosheets 22 and the second semiconductor channel material nanosheets 24) that is opposite the first sidewall mentioned above. Dielectric liner 27 is also present on a topmost surface of each of the second nanosheet stack, each dielectric wall structure 26, and, if present, at least one of the shallow trench isolation structures 25.

The various elements/components mentioned above and that are illustrated in FIG. 1 will now be described in greater detail. In the present application, the substrate can include a first semiconductor layer 10, an etch stop layer 12 and a second semiconductor layer 14. In embodiments, the first semiconductor layer 10 and/or the etch stop layer 12 can be omitted from the substrate. The first semiconductor layer 10 is composed of a first semiconductor material, and the second semiconductor layer 14 is composed of a second semiconductor material. The term “semiconductor material” is used throughout the present application to denote a material having semiconducting properties. Examples of semiconductor materials that can be used in the present application in providing the first semiconductor material and the second semiconductor material include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the second semiconductor layer 14 can be compositionally the same as, or compositionally different from, the first semiconductor material that provides the first semiconductor layer 10.

In some embodiments of the present application, the etch stop layer 12 can be composed of a dielectric material such as, for example, silicon dioxide and/or boron nitride. In other embodiments of the present application, the etch stop layer 12 is composed of a semiconductor material that is compositionally different from the first semiconductor material that provides the first semiconductor layer 10 and the second semiconductor material that provides the second semiconductor layer 14. In one example, the first semiconductor layer 10 is composed of silicon, the etch stop layer 12 is composed of silicon dioxide, and the second semiconductor layer 14 is composed of silicon. In another example, the first semiconductor layer 10 is composed of silicon, the etch stop layer 12 is composed of silicon germanium, and the second semiconductor layer 14 is composed of silicon.

The substrate including the first semiconductor layer 10, the etch stop layer 12 and the second semiconductor layer 14 can be formed utilizing techniques well known to those skilled in the art. For example, the substrate including the first semiconductor layer 10, the etch stop layer 12 and the second semiconductor layer 14 can be formed by a separation by ion implantation of oxygen process, or wafer bonding. Alternatively, the substrate including the first semiconductor layer 10, the etch stop layer 12 and the second semiconductor layer 14 can be formed by deposition of the various substrate layers one on top the other. The deposition used in forming the various substrate layers can include, but is not limited to, chemical vapor deposition (CVD), plasma enhanced chemical vapor deposition (PECVD), or epitaxial growth. The terms “epitaxial growth” or “epitaxially growing” means the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 450° C. to 900° C. Although higher temperature typically results in faster deposition, the faster deposition may result in crystal defects and film cracking.

As mentioned above, the first nanosheet stack includes alternating first sacrificial semiconductor material nanosheets 16 and first semiconductor channel material nanosheets 18. In some embodiments and as is illustrated in FIG. 1, the first nanosheet stack can include ‘n’ number of first semiconductor channel material nanosheets 18 and ‘n+1’ number of first sacrificial semiconductor material nanosheets 16, wherein n is an integer greater than one. By way of one example, the first nanosheet stack can include three first sacrificial semiconductor material nanosheets 16 and two first semiconductor channel material nanosheets 18. In the illustrated first nanosheet stack, each first semiconductor channel material nanosheet 18 is sandwiched between a bottom first sacrificial semiconductor material nanosheet and a top first sacrificial semiconductor material nanosheet. Each first sacrificial semiconductor material nanosheet 16 is composed of a third semiconductor material, while each first semiconductor channel material nanosheet 18 is composed of a fourth semiconductor material that is compositionally different from the third semiconductor material. In some embodiments, the fourth semiconductor material that provides each first semiconductor channel material nanosheet 18 can provide high channel mobility for NFET devices. In other embodiments, the fourth semiconductor material that provides each first semiconductor channel material nanosheet 18 can provide high channel mobility for PFET devices. The third semiconductor material that provides each first sacrificial semiconductor material nanosheet 16, and the fourth semiconductor material that provides each first semiconductor channel material nanosheet 18 can include one of the semiconductor materials mentioned above. In one example, the third semiconductor material that provides each first sacrificial semiconductor material nanosheet 16 is composed of a silicon germanium alloy having a germanium content from 20 atomic percent to 40 atomic percent and the fourth semiconductor material that provides each first semiconductor channel material nanosheet 18 is composed of silicon. Other combinations of semiconductor materials are possible as long as the third semiconductor material is compositionally different from the fourth semiconductor material.

As mentioned above, the second nanosheet stack includes alternating second sacrificial semiconductor material nanosheets 22 and second semiconductor channel material nanosheets 24. In some embodiments and as is illustrated in FIG. 1, the second nanosheet stack can include ‘m’ number of second semiconductor channel material nanosheets 24 and ‘m+1’ number of second sacrificial semiconductor material nanosheets 22, wherein m is an integer greater than one. Note that m can be equal to or different from n. By way of one example, the second nanosheet stack can include four second sacrificial semiconductor material nanosheets 22 and three second semiconductor channel material nanosheets 24. In the illustrated second nanosheet stack, each second semiconductor channel material nanosheet 24 is sandwiched between a bottom second sacrificial semiconductor material nanosheet and a top second sacrificial semiconductor material nanosheet. Each second sacrificial semiconductor material nanosheet 22 is composed of the third semiconductor material, while each second semiconductor channel material nanosheet 24 is composed of a fifth semiconductor material that is compositionally different from the third semiconductor material; the fifth semiconductor material can be compositionally the same as, or compositionally different than, the fourth semiconductor material. In some embodiments, the fifth semiconductor material that provides each second semiconductor channel material nanosheet 24 can provide high channel mobility for NFET devices. In other embodiments, the fifth semiconductor material that provides each second semiconductor channel material nanosheet 24 can provide high channel mobility for PFET devices. The third semiconductor material that provides each second sacrificial semiconductor material nanosheet 22, and the fifth semiconductor material that provides each second semiconductor channel material nanosheet 24 can include one of the semiconductor materials mentioned above. In one example, the third semiconductor material that provides each second sacrificial semiconductor material nanosheet 22 is composed of a silicon germanium alloy having a germanium content from 20 atomic percent to 40 atomic percent and the fifth semiconductor material that provides each second semiconductor channel material nanosheet 24 is composed of silicon or germanium. Other combinations of semiconductor materials are possible as long as the third semiconductor material is compositionally different from the fifth semiconductor material.

The middle dielectric isolation layer 20 is composed of a dielectric material such as for example, silicon dioxide, SiN, SiBCN, SiOCN or SiOC. In the present application, the middle dielectric isolation layer 20 is sandwiched between the first nanosheet stack and the second nanosheet stack. The middle dielectric isolation layer 20 provides a horizontal boundary between the first (bottom) device region and the second (top) device region.

Each shallow trench isolation structure 25 is composed of a trench dielectric material such as, for example, silicon oxide. In some embodiments, a trench dielectric liner composed of, for example, SiN, can be present along a sidewall and a bottom wall of the trench dielectric material. The shallow trench isolation structure 25 has a topmost surface that is substantially coplanar with, or slightly below, a topmost surface of the second semiconductor layer 14. The height of each shallow trench isolation structure 25 can be the same or different. For example, the height of the shallow trench isolation structure 25 that is located beneath the middle dielectric wall structure shown in FIG. 1 can be different from the height of the other shallow trench isolation structures 25 that flank that middle dielectric wall structure.

Each dielectric wall structure 26 is composed of one or more dielectric materials. The dielectric material(s) that provide the dielectric wall structure 26 is typically compositionally different from at least the dielectric material that provides the middle dielectric isolation layer 20. The dielectric material(s) that provide(s) the dielectric wall structure 26 can be composed of silicon oxide, a silicon carbon based dielectric material such as, for example, silicon carbide or a dielectric including atoms of Si, C and O, or any combination of the same. Other dielectric materials besides the ones listed can be employed in the present application in providing the dielectric wall structure 26.

The dielectric liner 27 is composed of a dielectric material that is typically compositionally different from at least the dielectric material that provides the dielectric wall structure 26 and/or the middle dielectric isolation layer 20. The dielectric liner 27 can be composed of, for example, silicon oxide, silicon nitride or SiBCN. The dielectric liner 27 is typically a conformal layer having a thickness typically from 2 nm to 5 nm. The term “conformal” denotes that a layer has a same thickness as measured from a horizontal surface of another layer as a thickness as measured from a vertical surface of the another layer.

The exemplary semiconductor structure illustrated in FIG. 1 can be formed utilizing well known processing steps. Notably, a first wafer including at least the second semiconductor layer 14 and a non-patterned first material stack of blanket layers of alternating third semiconductor material and fourth semiconductor material is provided. The blanket layers of alternating third semiconductor material and fourth semiconductor material can be formed by, for example, CVD, PECVD, epitaxial growth or any combination of such deposition processes. In some embodiments, the first wafer also includes a blanket layer of the dielectric material that provides a portion of, or an entirety of, the middle dielectric isolation layer 20, deposited on the non-patterned first nanosheet stack. The deposition of the blanket layer of dielectric material can include CVD, PECVD, or physical vapor deposition (PVD). A second wafer including a handler substrate and a non-patterned second material stack of blanket layers of alternating third semiconductor material and fifth semiconductor material is also provided. The blanket layers of alternating third semiconductor material and fifth semiconductor material can be formed by, for example, CVD, PECVD, epitaxial growth or any combination of such deposition processes. In some embodiments, the second wafer also includes a blanket layer of the dielectric material that provides a portion of, or an entirety of, the middle dielectric isolation layer 20, deposited on the non-patterned second nanosheet stack. The first and second wafers are then bonded together such that the blanket layer of the dielectric material is located between the first and second non-patterned material stacks. The handler wafer is removed after wafer bonding. In some embodiments, a sacrificial etch stop layer can be present on the handler wafer prior to forming the non-patterned second material stack. This sacrificial etch stop layer is removed after wafer bonding. Removal of the handler wafer and the sacrificial etch stop layer can be performed utilizing one or more material removal processes. In an example, the handler substrate is removed by planarization (chemical mechanical polishing (CMP) or grinding), and the sacrificial etch stop layer can be removed utilizing an etching process.

A first nanosheet patterning process can be performed on the non-patterned second material stack, the blanket layer of dielectric material, and the non-patterned first material stack. The first nanosheet patterning process includes lithography and etching. Lithography includes forming a photoresist material on a layer or stack of material layers that need to be patterned, exposing the photoresist material to a desired pattern of irradiation, and thereafter developing the exposed photoresist material utilizing a conventional resist developer. The developed photoresist material has a desired pattern (i.e., nanosheet pattern) that is then transferred to the layer or stack of material layers that need to be patterned by etching. Etching can include dry etching and/or chemical wet etching. In one embodiment, a dry etch such as, for example, reactive ion etching (RIE), ion beam etching (IBE), plasma etching or any combination thereof can be used to transfer the pattern to the layer or stack of material layers that need to be patterned. The first nanosheet patterning process converts the blanket layer of dielectric material into the middle dielectric isolation layer 20, and the non-patterned first material stack into the first nanosheet stack mentioned above. The first nanosheet patterning process provides the first width to both the middle dielectric isolation layer 20 and the first nanosheet stack. The first nanosheet patterning process also converts the non-patterned second material stack into a precursor second nanosheet stack. The precursor second nanosheet stack has the first width mentioned above. A second nanosheet patterning process can then be performed to reduce the width of the precursor second nanosheet stack to provide the second nanosheet stack having the second width mentioned above. Each of the twice nanosheet patterned structures includes the first nanosheet stack, the middle dielectric isolation layer 20 and the second nanosheet stack mentioned above.

Next, the shallow trench isolation structures 25 can be formed by etching a trench into the second semiconductor layer 14, depositing the optional trench dielectric liner material and the trench dielectric material in the trench, and thereafter performing an etch back process.

Dielectric wall structure 26 can thereafter be formed by deposition of a dielectric layer such that the dielectric layer merges or pinches off in the small gap that is adjacent to each neighboring pairs of first and second nanosheet stacks. An isotropic removal process is then performed to remove the dielectric layer in areas in which pinch off did not occur.

Dielectric liner 27 is then formed by utilizing a conformal deposition process such as, for example, CVD, PECVD or ALD.

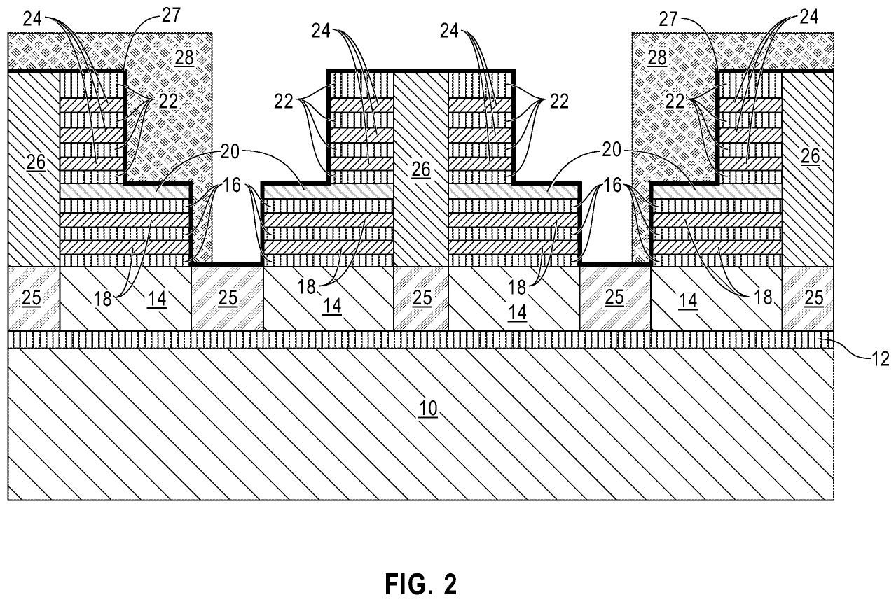

Referring now to FIG. 2, there is illustrated the exemplary semiconductor structure shown in FIG. 1 after forming a patterned mask 28 that reveals an area in which a neighboring pair of first and second nanosheet stacks are spaced apart by one of the dielectric wall structures 26. The patterned mask 28 is composed of any masking material or stack of masking materials that are well known to those skilled in the art. The patterned mask 28 can be formed by deposition of the masking material or a stack of masking materials, and thereafter patterning the as-deposited masking material or as-deposited stack of masking materials by lithography and etching. The area that is revealed (i.e., is not protected by the patterned mask 28) includes a neighboring pair of first and second nanosheet stacks that are spaced apart by one of the dielectric wall structures 26. In the illustrated embodiment, the middle dielectric wall structure is not protected by the patterned mask 28. The patterned mask 28 is used in the present application as a mask during a subsequent recess etch that reduces the height of the dielectric wall structure 26 that is not protected by the patterned mask 28.

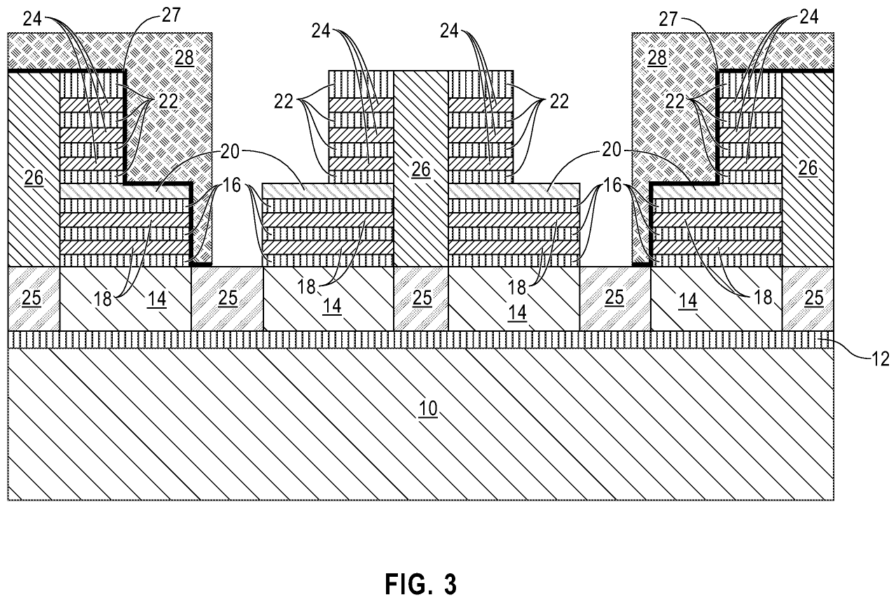

Referring now to FIG. 3, there is illustrated the exemplary semiconductor structure shown in FIG. 2 after revealing the neighboring pair of first and second nanosheet stacks and the dielectric wall structure 26 that are not protected by the patterned mask 28. The revealing the neighboring pair of first and second nanosheet stacks and the dielectric wall structure 26 that are not protected by the patterned mask 28 includes an etching process that is selective in removing the physically exposed portion of the dielectric liner 27. The etching process can include, for example, RIE.

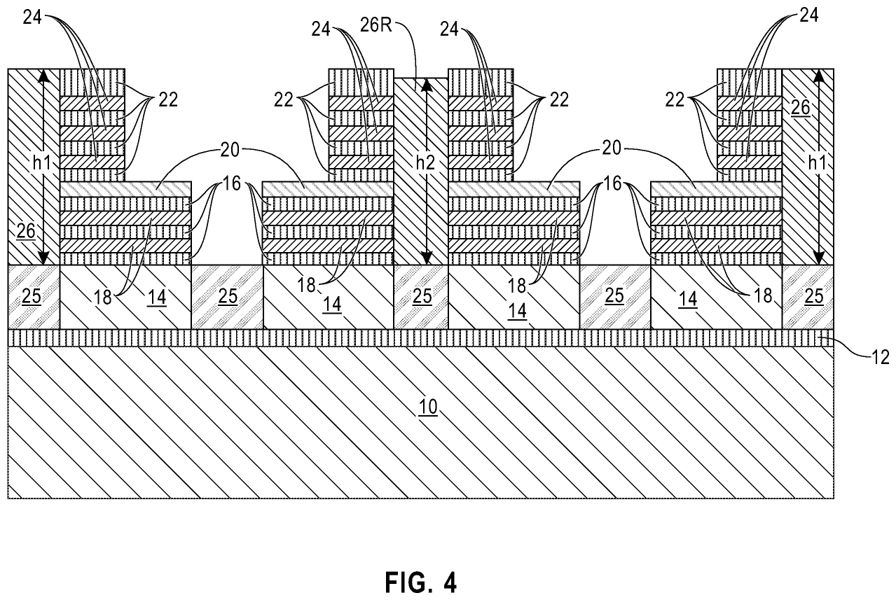

Referring now to FIG. 4, there is illustrated the exemplary semiconductor structure shown in FIG. 3 after reducing the height of the revealed dielectric wall structure and removing the patterned mask 28. The reducing of the height of the revealed dielectric wall structure provides a recessed (or reduced height) dielectric wall structure 26R. The recessed (or reduced height) dielectric wall structure 26R has a second height, h2, that is less than the first height, h1, of the dielectric wall structures 26 that are protected by the patterned mask 28. The reducing of the height of the revealed dielectric wall structure can be performed utilizing an etching process, such as, RIE, that is selective in removing a portion of the revealed dielectric wall structure. The etching process used in reducing the height of the revealed dielectric wall structure does not remove any portion of the first and second nanosheet stacks and the middle dielectric isolation layer 20 that are not protected by the patterned mask 28. The formation of the recessed dielectric wall structure 26 will permit the subsequent formation of an area including a neighboring pair of stacked forksheet devices separated by the recessed dielectric wall structure 26R in which the gate electrode of each of the top forksheet devices (i.e., top transistors) of the neighboring pair of stacked forksheet devices is shared and is present on top of the recessed dielectric wall structure 26R.

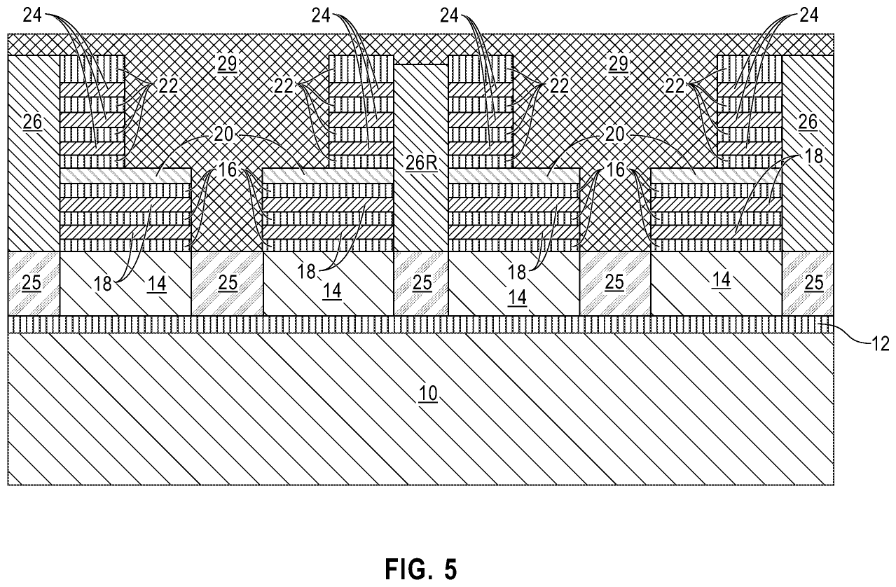

After reducing the height of the revealed dielectric wall structure, the patterned mask 28 and the dielectric liner 27 are removed utilizing one or more material removal processes prior to proceeding to the next processing step as shown in FIG. 5.

Referring now to FIG. 5, there is illustrated the exemplary semiconductor structure shown in FIG. 4 after forming a sacrificial gate material 29. The sacrificial gate material 29 can be composed of, for example, polysilicon, amorphous silicon, amorphous silicon germanium or amorphous germanium. The sacrificial gate material 29 can be formed by a deposition process such as, for example, CVD, PECVD, PVD or ALD. The sacrificial gate material 29 can be formed by a deposition process such as, for example, CVD, PECVD, PVD or ALD. The sacrificial gate material 29 is formed on and between the multiple twice nanosheet patterned structures as well as on top of each dielectric wall structure 26 and the recessed dielectric wall structure 26R. The sacrificial gate material 29 has a topmost surface that extends above the topmost surface of the second nanosheet stack of each twice nanosheet patterned structure.

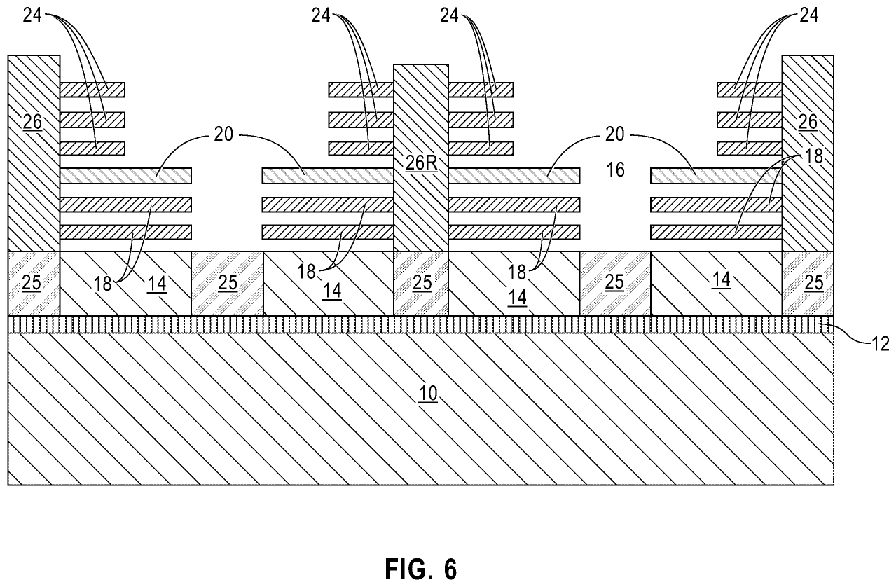

Referring now to FIG. 6, there is illustrated the exemplary semiconductor structure shown in FIG. 5 after forming gate spacers (not shown), inner spacers (not shown), bottom and top source/drain regions (not shown) removing the sacrificial gate material 29, and suspending each first semiconductor channel material nanosheet 18 of the first nanosheet stack and each second semiconductor channel material nanosheet 24 of the second nanosheet stack.

The gate spacers and inner spacers are not shown in the cross view provided. Instead, the gate spacers and inner spacers would be formed into and out of the plane of the drawings sheet containing FIG. 6. The gate spacers include a conventional gate dielectric spacer material and they can be formed by deposition and a spacer etch. The inner spacers are formed by first recessing, i.e., indenting, each of the first sacrificial semiconductor material nanosheets 16 and each of the second sacrificial semiconductor material nanosheets 22. After the recessing step, a gap is formed at the ends of each of the first sacrificial semiconductor material nanosheets 16 and each of the second sacrificial semiconductor material nanosheets 22. The recessing includes a lateral etching process that removes end portions of each first sacrificial semiconductor material nanosheets 16 and each of the second sacrificial semiconductor material nanosheets 22. This lateral etch does not indent the first semiconductor channel material nanosheets 18 or the second semiconductor channel material nanosheets 24. Next, a layer of an inner spacer dielectric material is formed by a deposition process such as, for example, CVD, PECVD or ALD. This layer of inner spacer dielectric material fills in each of the gaps and is formed along a sidewall of each first semiconductor channel material nanosheet 18, the middle dielectric isolation layer 20 and each second semiconductor channel material nanosheet 24. During the deposition of the inner spacer dielectric material, the inner spacer dielectric material pinches in the gaps created above. The inner spacer dielectric material can include, but is not limited to, silicon dioxide, SiN, SiBCN, SiOCN or SiOC. After depositing the layer of inner spacer dielectric material, an isotropic etch back process is performed on the layer of spacer dielectric material. The isotropic etch back process removes the layer of inner spacer dielectric material that is present on the sidewalls of the each first semiconductor channel material nanosheet 18, the middle dielectric isolation layer 20 and each second semiconductor channel material nanosheet 24, while maintaining the layer of inner spacer dielectric material in each gaps. The maintained layer of inner spacer dielectric material within each of the gaps provides the inner spacers.

Although not shown, bottom source/drain regions and top source/drain regions can be formed after inner spacer formation utilizing techniques well known to those skilled in the art. The bottom source/drain regions and the top source/drain regions would run into and out of the plane of the drawing sheet including FIG. 6. The bottom source/drain regions and the top source/drain regions are typically formed by an epitaxial growth process. As used herein, a “source/drain” region can be a source region or a drain region depending on subsequent wiring and application of voltages during operation of the FET. In the present application, the bottom source/drain regions are formed first, followed by forming a source/drain separating dielectric layer, and thereafter the second source/drain regions are formed. The bottom and top source/drain regions include a semiconductor material and a dopant. The semiconductor material that provides each source/drain region can include one of the semiconductor materials mentioned above for the first semiconductor layer 10. The semiconductor material that provides the source/drain regions can be compositionally the same, or compositionally different from each semiconductor channel material nanosheet that is present in the respective device region, i.e., top device region and bottom device region. The dopant that is present in each source/drain region can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each source/drain region can have a dopant concentration of from 4×10²⁰ atoms/cm³ to 3×10²¹ atoms/cm³. In one example, each bottom source/drain region is composed of phosphorus doped silicon.

After gate spacer, inner spacer and source/drain formation, the sacrificial gate material 29 is removed to reveal each twice nanosheet patterned structure. In embodiments, an interlayer dielectric (ILD) material layer can be deposited, and a chemical mechanical polishing step can be used to reveal the sacrificial gate material 29. The sacrificial gate material 29 can be removed utilizing a material removal process such as, for example, etching, which is selective in removing the sacrificial gate material 29.

After sacrificial gate material 29 removal, each first sacrificial semiconductor material nanosheet 16 and each second sacrificial semiconductor material nanosheet 22 are removed to suspend each first semiconductor channel material nanosheet 18, the middle dielectric isolation layer 20, and each second semiconductor channel material nanosheet 24 as is shown in FIG. 6. The suspended first semiconductor channel material nanosheets 18, the suspended middle dielectric isolation layer 20, and the suspended second semiconductor channel material nanosheet 24 are anchored in place by the dielectric wall structure 26 (or the recessed dielectric wall structure 26R). The removal of each first sacrificial semiconductor material nanosheet 16 and each second sacrificial semiconductor material nanosheet 22 is performed utilizing any material removal process such as, for example, etching, which is selective in removing the third semiconductor material that was used in providing the first sacrificial semiconductor material nanosheets 16 and the second sacrificial semiconductor material nanosheets 22. This removal process does not remove each first semiconductor channel material nanosheet 18, the middle dielectric isolation layer 20, and each second semiconductor channel material nanosheet 24.

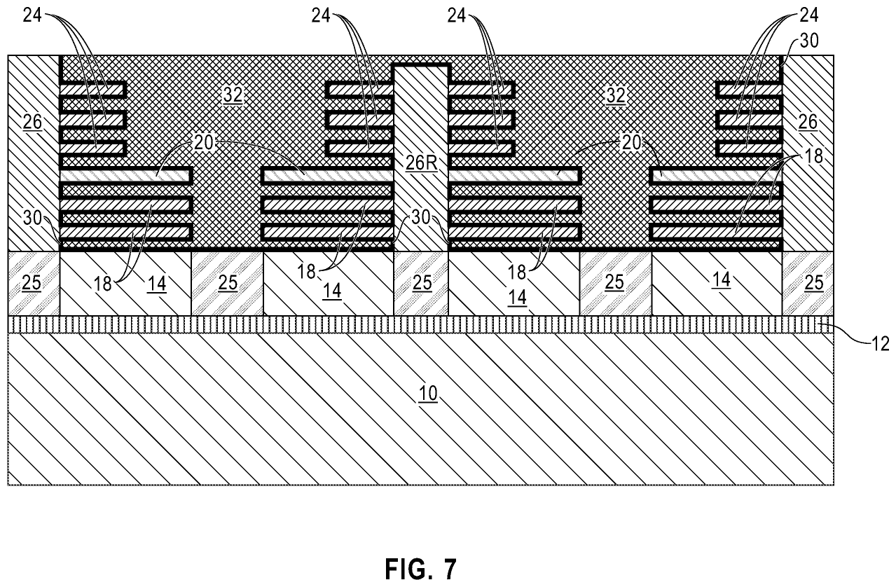

Referring now to FIG. 7, there is illustrated the exemplary semiconductor structure shown in FIG. 6 after forming a first gate structure wrapping around and along a physically exposed sidewall of each first semiconductor channel material nanosheet 18 of the first nanosheet stack, the middle dielectric isolation layer 20 and each second semiconductor channel material nanosheet 24 of the second nanosheet stack, the first gate structure including a first gate dielectric layer 30 and a first gate electrode 32. In the present application, the first gate dielectric layer 30 is formed on top of the recessed dielectric wall structure 26R as shown in FIG. 7.

In the present application, the first gate dielectric layer 30 is formed directly on physically exposed surfaces of each first semiconductor channel material nanosheet 18, the middle dielectric isolation layer 20, and each second semiconductor channel material nanosheet 24. The first gate electrode 32 is formed on the first gate dielectric layer 30. The first gate dielectric layer 30 is composed of a first gate dielectric material that has a dielectric constant of greater than 3.9; all dielectric constants mentioned in this application are measured in a vacuum unless otherwise stated. Illustrative examples of first gate dielectric materials that can be used in providing the first gate dielectric layer 30 include, but are not limited to, hafnium dioxide (HfO₂), hafnium silicon oxide (HfSiO), hafnium silicon oxynitride (HfSiO), lanthanum oxide (La₂O₃), lanthanum aluminum oxide (LaA₁O₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The first gate dielectric material that provides the first gate dielectric layer 30 can further include dopants such as lanthanum (La), aluminum (Al) and/or magnesium (Mg).

The first gate electrode 32 is composed of a first gate electrode material. The first gate electrode material can include a first work function metal (WFM) and optionally a first conductive metal. The first WFM can be used to set a threshold voltage of the transistor to a desired value. In some embodiments, the first WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the first WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional first conductive metal can include, but is not limited to aluminum (Al), tungsten (W), or cobalt (Co). The first gate structure including the first gate dielectric layer 30 and the first gate electrode 32 can be formed by deposition of the first gate dielectric material and the first gate electrode material, followed by a planarization process which removes any first gate dielectric material and first gate electrode material that is formed on top of the dielectric wall structures 26. Note that a portion of the first gate electrode 32 of the first gate structure remains on top of the recessed dielectric wall structure 26R.

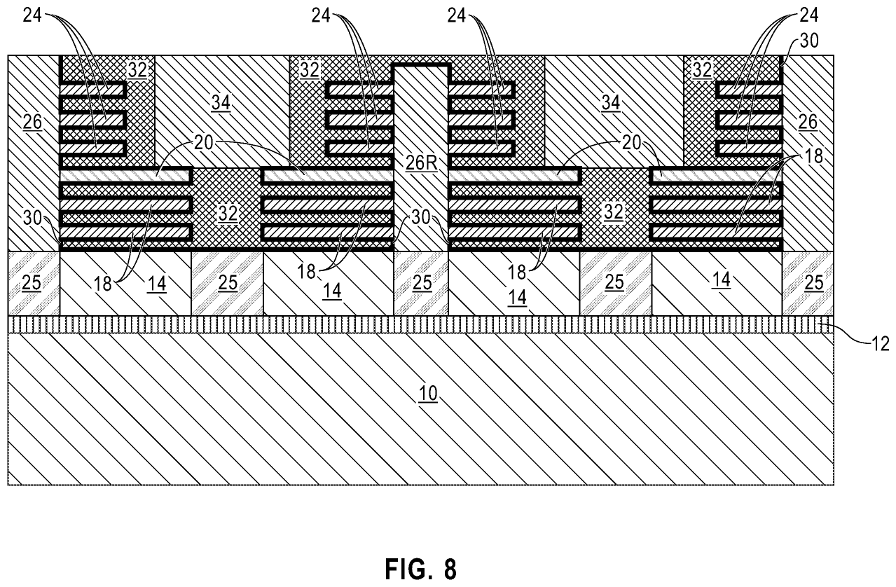

Referring now to FIG. 8, there is illustrated the exemplary semiconductor structure shown in FIG. 7 after forming a frontside gate cut structure 34. The frontside gate cut structure 34 is formed in the top device region including the suspended second semiconductor channel material nanosheets 24. The frontside gate cut structure 34 contacts the first gate dielectric layer 30 that is present on the middle dielectric isolation layers 20. In some embodiments, the first gate dielectric layer 30 can be etched during the formation of the frontside gate cut structure 34. In the illustrated embodiment, the frontside gate cut structure 34 spans over a neighboring pair of middle dielectric isolation layers 20. The frontside gate cut structure 34 electrically separates the top device region from the bottom device region. The frontside gate cut structure 34 has a topmost surface that is substantially coplanar to at least a topmost surface of the dielectric wall structures 26.

The frontside gate cut structure 34 is formed by a gate cut process. The gate cut process includes forming a gate cut masking layer (not shown) over the exemplary structure shown in FIG. 7. The gate cut masking layer has at least one opening that corresponds to a region in which a gate cut trench is to be subsequently formed. With the gate cut masking layer in place, an etch is used to remove a physically exposed portion of the first gate electrode 32 in the top device region. After forming the gate cut trench, the gate cut trench is filled with a gate cut dielectric material such as, for example silicon nitride, silicon oxide, or a combination thereof. The gate cut dielectric material can be formed utilizing a deposition process such as, for example, ALD, CVD or PECVD. A planarization process such as, for example, CMP can follow the deposition of the gate cut dielectric material. The gate cut dielectric material that remains in the gate cut trench provides the frontside gate cut structure 34. It is noted that the gate cut masking layer can be removed after this etch and prior to filling the gate cut trench utilizing another etching process, or it can be removed after filling process by the planarization step mentioned above.

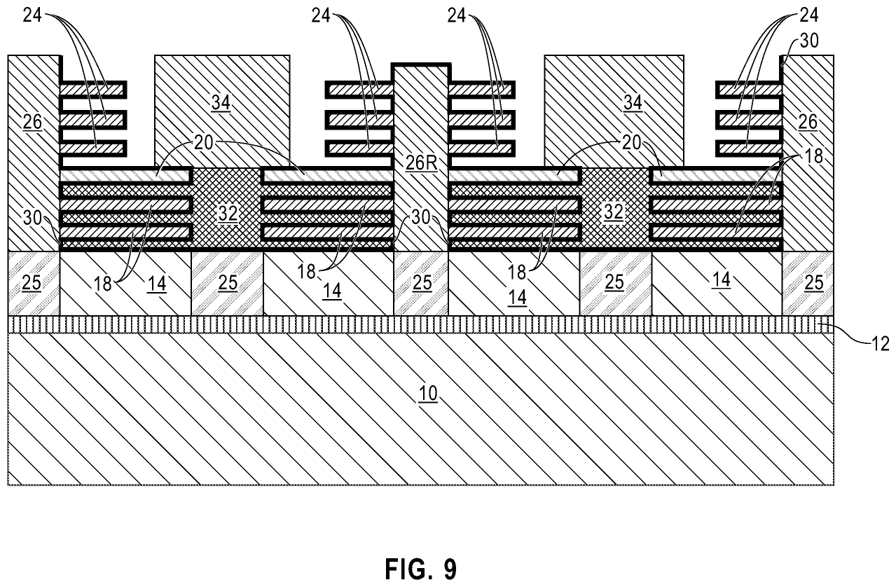

Referring now to FIG. 9, there is illustrated the exemplary semiconductor structure shown in FIG. 8 after removing the first gate electrode 32 that is in contact with each second semiconductor channel material nanosheet 24 of the second nanosheet stack. In some embodiments (not shown), the first gate dielectric layer 30 can also be removed from each second semiconductor channel material nanosheet 24 of the second nanosheet stack and from a topmost surface of the middle dielectric isolation layer 20 that is not covered by the frontside gate cut structure 34. The removal of the first gate dielectric layer 30 from the top device region is not preferred since it can raise the thermal budget of the processing flow. The removal of the first gate electrode 32 from the top device region can be performed utilizing a material removal process such as, for example, an etch, that is selective in removing the first gate electrode material. When the first gate dielectric layer 30 is removed from the top device region another material removal process such as, for example, an etch, that is selective in removing the first gate dielectric material.

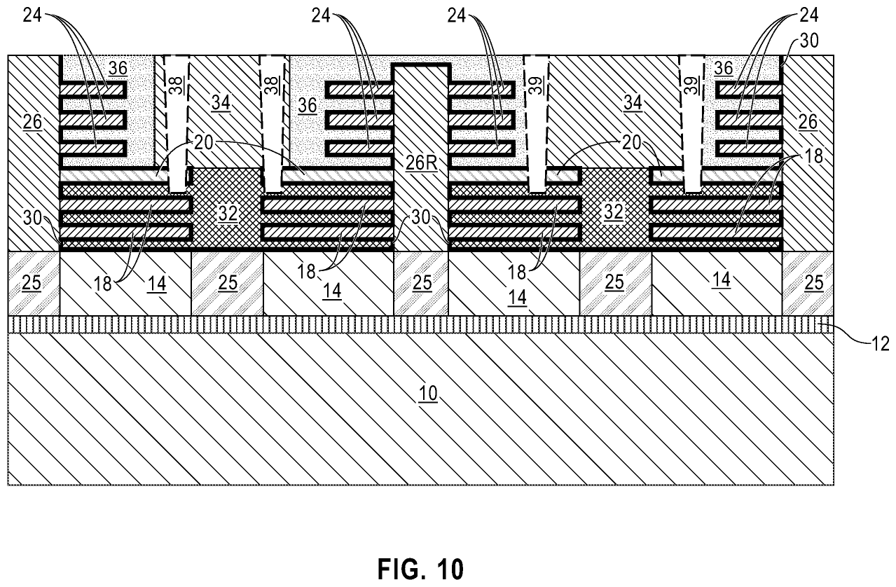

Referring now to FIG. 10, there is illustrated the exemplary semiconductor structure shown in FIG. 9 after forming a second gate electrode 36 in contact with each second semiconductor channel material nanosheet 24 of the second nanosheet stack, and forming frontside contact structures. The frontside bottom gate contact structures can include non-shared frontside bottom gate contact structures 38, shared frontside bottom gate contact structures 39 or any combination thereof. In embodiments in which the first gate dielectric layer 30 is removed from the top device region, a second gate dielectric layer (not shown) can be formed on the physically exposed surfaces of each second semiconductor channel material nanosheet 24, the middle dielectric isolation layer 20 and on top of the recessed dielectric wall structure 26R. In such embodiments, the second gate dielectric layer includes a second gate dielectric material that is typically, but not necessarily always, compositionally different from the first gate dielectric material. The second gate dielectric material can be selected from one of the first gate dielectric materials mentioned above. The second gate dielectric material can be formed by a deposition process such as, for example, CVD, PECVD or ALD.

The second gate electrode 36 is composed of a second gate electrode material which is typically compositionally different from the first gate electrode material. In embodiments, the second gate electrode material can include a second work function metal (WFM) and optionally a second conductive metal. The second WFM can be used to set a threshold voltage of the transistor to a desired value and can include one of the WFM materials mentioned above for the first WFM. The optional second conductive metal can include, but is not limited to aluminum (Al), tungsten (W), or cobalt (Co). The second gate electrode 36 can be formed by a deposition process such as, for example, CVD, PECVD or ALD.

In some embodiments, the first gate electrode 32 present in the bottom device region is composed of an n-type work function metal, while the second gate electrode 36 present in the top device region is composed of an n-type work function metal that is compositionally different from the n-type work function metal present in the bottom device region. In yet other embodiments, the first gate electrode 32 and the second gate electrode 36 are composed of a same n-type or p-type work function metal.

In some embodiments, the first gate electrode 32 present in the bottom device region is composed of a p-type work function metal, while the second gate electrode 36 present in the top device region is composed of a p-type work function metal that is compositionally different from the p-type work function metal present in the bottom device region. As previously mentioned, the first gate electrode 32 and the second gate electrode 36 can also be composed of a same n-type or p-type work function metal.

In some embodiments, the first gate electrode 32 present in the bottom device region is composed of an n-type work function metal, while the second gate electrode 36 present in the top device region is composed of a p-type work function metal.

In some embodiments, the first gate electrode 32 present in the bottom device region is composed of a p-type work function metal, while the second gate electrode 36 present in the top device region is composed of an n-type work function metal.

Thus, and in the present application, the structure that is formed can include a NFET stacked over another NFET, a PFET stacked over another PFET, a NFET stacked over a PFET or a PFET stacked over an NFET. In embodiments, the top device region and/or the bottom device region can have mixed NFETs and PFETs.

After performing the above replacement gate process in the top device region, frontside bottom gate contact structures are formed. In the illustrated embodiment, each frontside bottom gate contact structure is formed entirely through the frontside gate cut structure 34 and the middle dielectric isolation layer 20, and partially through the first gate electrode 32. Thus, and in this illustrated embodiment, each frontside bottom gate contact structure is formed in direct contact with the first gate electrode 32. As mentioned above, the frontside bottom gate contact structures can include non-shared frontside bottom gate contact structures 38, shared frontside bottom gate contact structures 39 or any combination thereof. In the present application, non-shared frontside bottom gate contact structures 38 are frontside bottom gate contact structures that are spaced apart from the second gate electrode 36 by a portion of the frontside gate cut structure 34. In such embodiments, independent gates (top and bottom) are formed. A pair of non-shared frontside bottom gate contact structures 38 is illustrated on the left hand side of FIG. 10. In the present application, shared frontside bottom gate contact structures 39 are frontside bottom gate contact structures that directly contact a sidewall of the second gate electrode 36. In such embodiments, a stacked forksheet transistor is formed that has shared top and bottom gates. A pair of shared frontside bottom gate contact structures 39 is illustrated on the right hand side of FIG. 10. In some embodiments, the present application can form both types (i.e., shared frontside bottom gate contact structures 39 and non-shared frontside bottom gate contact structures 38) of frontside bottom gate contact structures as is shown in FIG. 10. In other embodiments, only shared frontside bottom gate contact structures 39 are formed. In yet other embodiments, only non-shared frontside bottom gate contact structures 38 are formed. The present application permits the formation of various frontside contact schemes.

Notwithstanding the type or types of frontside bottom gate contact structures that are formed, each frontside bottom gate contact structure can be formed by first forming a frontside bottom gate contact structure trench into the frontside gate cut structure 34, the middle dielectric isolation layer 20 (in some embodiments the fronted contact structure trench not need pass through the middle dielectric isolation layer 20), and the first gate electrode 32. The frontside bottom gate contact structure trench can be formed by lithography and etching. The frontside bottom gate contact structure trench is then filled (including deposition and planarization) with at least a contact conductor material. The contact conductor material that can be used for providing each frontside bottom gate contact structure includes, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. Each frontside bottom gate contact structure can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above.

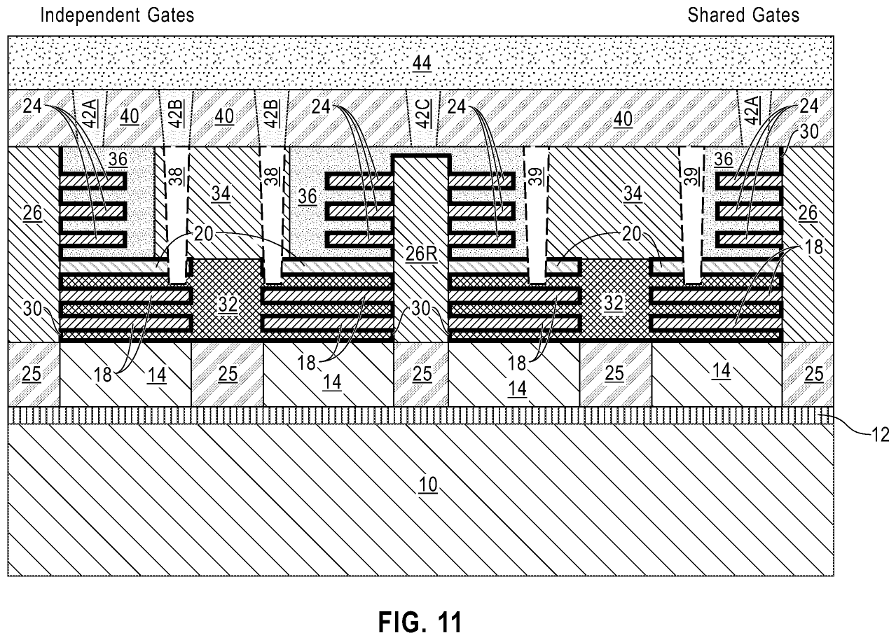

Referring now to FIG. 11, there is illustrated the exemplary semiconductor structure shown in FIG. 10 after forming a MOL dielectric layer 40 and a frontside BEOL interconnect structure 44, wherein the MOL dielectric layer 40 includes MOL contact structures embedded therein. The MOL dielectric layer 40 is composed of a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer, or any combination thereof. The term “low-k” as used throughout the present application denotes a dielectric material that has a dielectric constant of less than 4.0 The MOL dielectric layer 40 can be formed by a deposition process including, but not limited to, CVD, PECVD or spin-on coating. A planarization process such as, for example, CMP follows the deposition process.

A metallization process is then used to form MOL contact structures in the MOL dielectric layer 40. The metallization process includes the processing steps mentioned above in forming the frontside contact structures. MOL contact structures also includes materials mentioned above for providing the frontside contact structures. The MOL contact structures that can be formed include a top gate MOL contact structure 42A, a bottom gate MOL contact structure 42B, a shared top gate MOL contact structure 42C or any combination of such MOL contact structures. In the present disclosure, top gate MOL contact structure 42A directly contacts a second gate electrode 36 that is not shared, the bottom gate MOL contact structure 42B directly contacts the non-shared frontside bottom gate contact structure 38, and the shared top gate MOL contact structure 42C directly contacts the second gate electrode 36 that the spans on top of the recessed dielectric wall structure 26R. FIG. 11 illustrated an embodiment in which all three types of MOL contact structures are formed. In other embodiments, it is possible to omit at least one of the types of MOL contact structures. This allows for flexibility in wiring of the stacked forksheet transistors.

In some embodiments in which independent gates (top and bottom) are formed, the MOL contact structures can include top gate MOL contact structure 42A and a bottom gate MOL contact structure 42B which is connected to the bottom gate via the frontside bottom gate contact structure 38. This embodiment is shown on the left hand side of FIG. 11. In other embodiments in which shared gates (top and bottom) are formed, shared top gate MOL contact structure 42C and top gate MOL contact structure 42A are formed; in this embodiment the top and bottom gates are interconnected by the shared frontside bottom gate contact structure 39. This embodiment is shown on the right hand side of FIG. 11. The MOL contact structures typically have a topmost surface that is substantially coplanar with a topmost surface of the MOL dielectric layer 40.

Next, BEOL interconnect structure 44 is formed on the MOL dielectric layer 40 utilizing techniques well known to those skilled in the art. For example, the BEOL interconnect structure 44 can be formed utilizing a single damascene or a dual damascene process. The BEOL interconnect structure 44 includes at least one interconnect level that includes electrically conductive structures (not separately shown), such as, for example, Cu structures, embedded in an interconnect dielectric material layer (not separately shown), such as, for example, one of the dielectric materials mentioned above for the MOL dielectric layer 40. The BEOL interconnect structure 44 contacts each of the MOL contact structures to complete the frontside wiring of each stacked forksheet transistor.

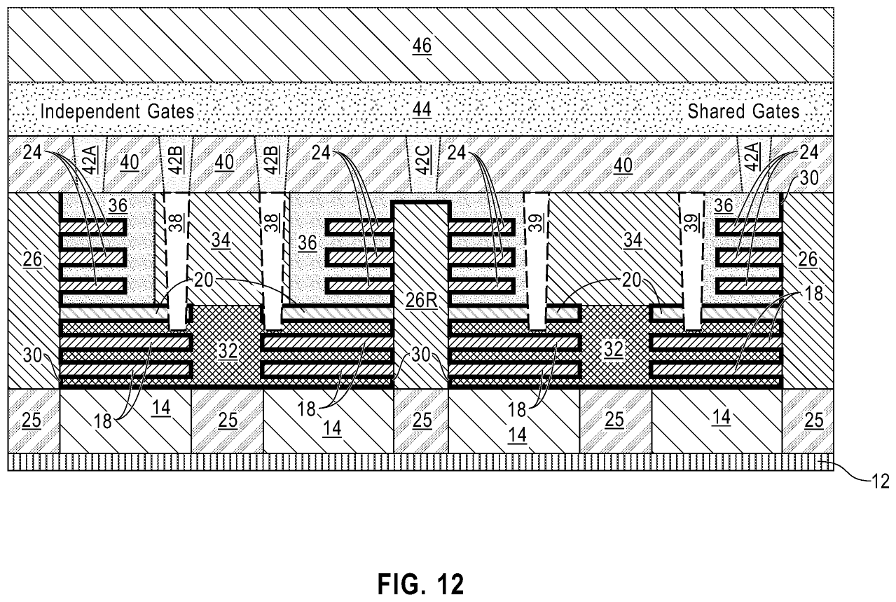

Referring now to FIG. 12, there is illustrated the exemplary semiconductor structure shown in FIG. 11 after forming a carrier wafer 46 on the frontside BEOL interconnect structure 44, and removing a first semiconductor layer 10 of the substrate. Carrier wafer 46 is formed on the BEOL interconnect structure 44 utilizing techniques, such as, for example, wafer bonding, which are well known to those skilled in the art. The carrier wafer 46 can include one of the semiconductor materials mentioned above for the first semiconductor layer 10. The use of the carrier wafer 46 permits backside processing of the exemplary structure. Backside processing includes flipping the structure 180°, and then removing the first semiconductor layer 10 if that layer is present. The flipping step is not shown in FIG. 12 for clarity. The flipping of the structure can be performed manually or utilizing a robot arm. This flipping revels a backside surface of first semiconductor layer 10 if the same is present. The reveled first semiconductor layer 10 is then removed utilizing an etching process that is selective in removing the first semiconductor layer 10. The etching process stops on the etch stop layer 12 if the same is present. Note that the carrier wafer 46 is typically removed from the final structure.

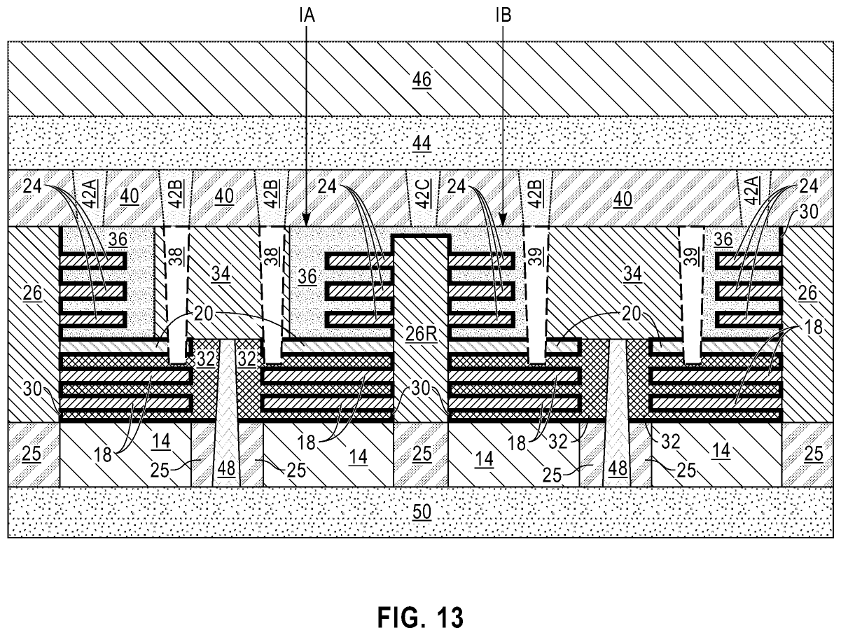

Referring now to FIG. 13, there is illustrated the exemplary semiconductor structure shown in FIG. 12 after removing the etch stop layer 12 of the substrate, forming a backside gate cut structure 48 and a backside interconnect structure 50. Etch stop layer 12 is removed utilizing an etching process that is selective in removing the etch semiconductor layer 12. The etching process stops on the second semiconductor layer 14. Backside gate cut structure 48 cuts the first gate electrode 32 as shown in FIG. 13. The backside gate cut structure 48 can be formed utilizing the processing technique mentioned above in forming the frontside gate cut structure 34. The backside gate cut structure 48 can include one of the dielectrics mentioned above for the frontside gate cut structure 34. In the present application, the backside gate cut structure 48 passes through one of the shallow trench isolation structures 25 (if the same is present), the first gate dielectric layer 30 that is present on a surface of the second semiconductor layer 14, and the first gate electrode 32, and the backside gate cut structure 48 contacts a bottom surface of the frontside gate cut structure 34.

Backside interconnect structure 50 is formed on a physically exposed surface of the second semiconductor layer 14. The backside interconnect structure 50 contact each backside gate cut structure 48. The backside interconnect structure 50 can be formed utilizing the materials and techniques mentioned above in forming the frontside BEOL interconnect structure 44. The backside interconnect structure 50 can be used in some embodiments as a backside power distribution network.

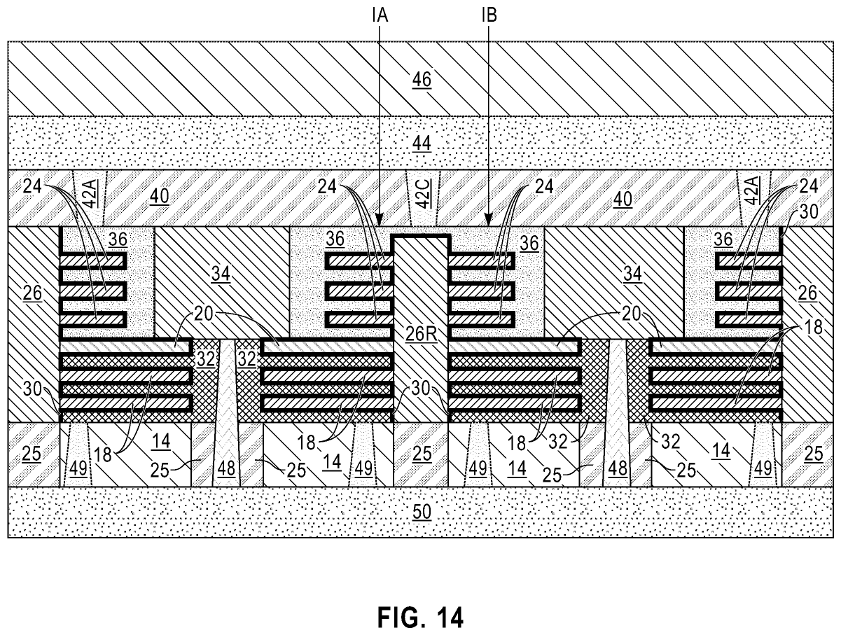

Referring now to FIG. 14, there is illustrated an exemplary semiconductor structure including a plurality of stacked forksheet transistors in accordance with another embodiment of the present application. The exemplary semiconductor structure is similar to the one depicted in FIG. 13 except for replacing the frontside bottom gate contact structures with backside bottom gate contact structures 49. Since backside bottom gate contact structures 49 are employed in contacting the first gate electrode 32, there is no need to form bottom gate MOL contact structure 42B. The backside bottom gate contact structures 49 are formed into the second semiconductor layer 14 by metallization as described above, and the backside bottom gate contact structures 49 include materials mentioned above for providing the frontside contact structures.

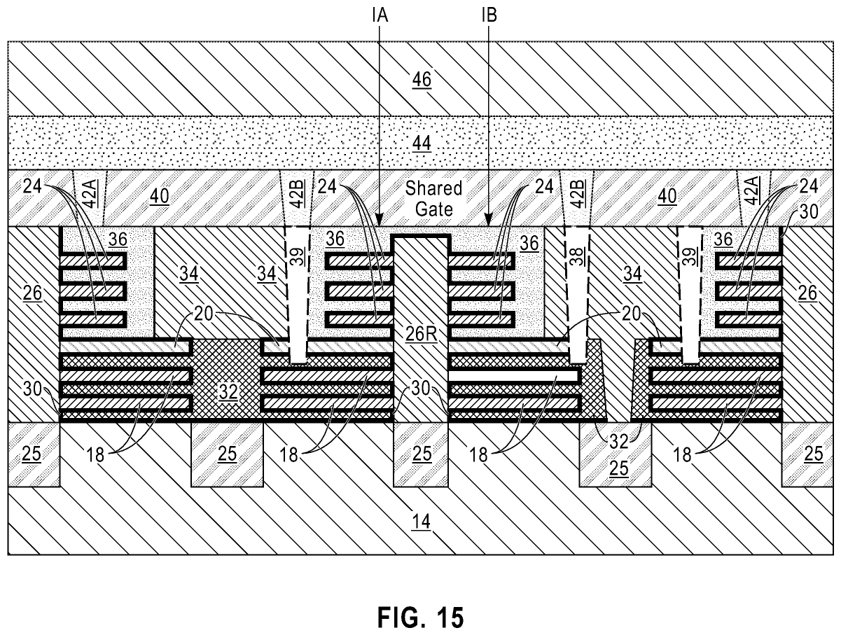

Referring now to FIG. 15, there is illustrated an exemplary semiconductor structure including a plurality of stacked forksheet transistors in accordance with yet another embodiment of the present application. In this embodiment, the initial substrate can include one in which only the second semiconductor layer 14 is employed. As such, no backside processing typically occurs with this embodiment of the present application. Although FIG. 15 illustrates the presence of a carrier wafer 46 on top of the frontside BEOL interconnect structure 44, embodiments include omitting the carrier wafer 46 from the structure. The structure illustrated in FIG. 15 includes similar elements to those illustrated and described above in regard to the structure shown in FIG. 13. It is further noted that on the right hand side of FIG. 15, the frontside gate cut structure 34 extends between the first gate electrode 32. This structural variation is achieved by utilizing a two-step patterning process to remove the first gate electrode 32 from the top and bottom areas prior to forming the frontside gate cut structure 34.

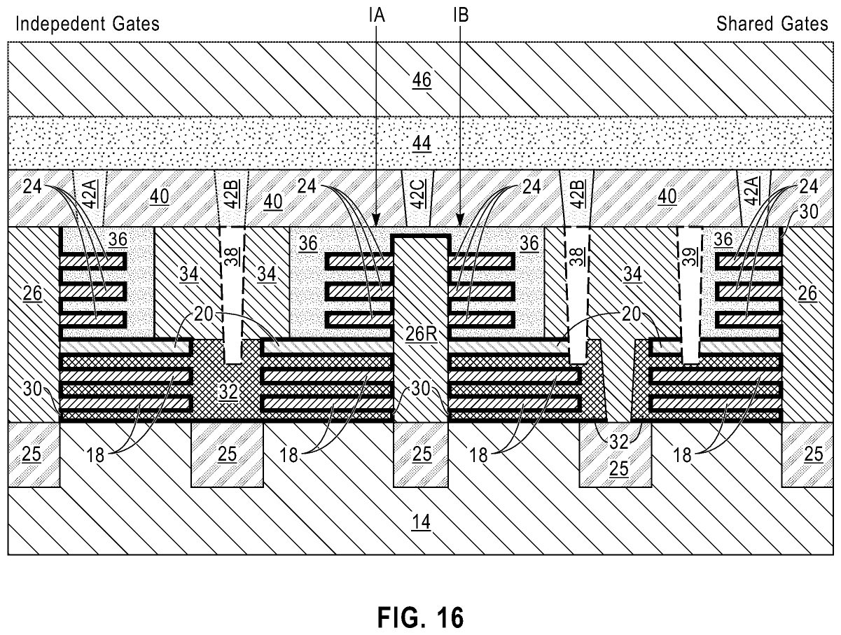

Referring now to FIG. 16, there is illustrated an exemplary semiconductor structure including a plurality of stacked forksheet transistors in accordance with yet another embodiment of the present application. The illustrated structure shown in FIG. 16 is similar to the one illustrated in FIG. 15 except for the frontside wiring configuration and that a non-shared frontside bottom gate contact structure 38 is formed in the middle of the frontside gate cut structure 34 and that this non-shared frontside bottom gate contact structure 38 does not pass through the middle dielectric isolation layer 20 as in the previous embodiments of the present application. Although FIG. 16 illustrates the presence of a carrier wafer 46 on top of the frontside BEOL interconnect structure 44, embodiments include omitting the carrier wafer 46 from the structure.

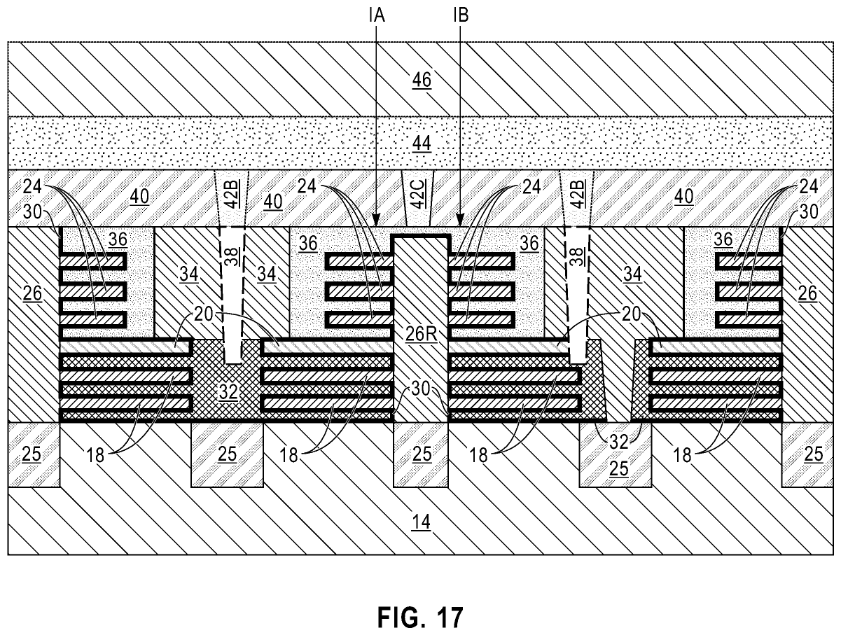

Referring now to FIG. 17, there is illustrated an exemplary semiconductor structure including a plurality of stacked forksheet transistors in accordance with a further embodiment of the present application. The illustrated structure shown in FIG. 17 is similar to the one illustrated in FIG. 16 except for the frontside wiring configuration. Although FIG. 17 illustrates the presence of a carrier wafer 46 on top of the frontside BEOL interconnect structure 44, embodiments include omitting the carrier wafer 46 from the structure.

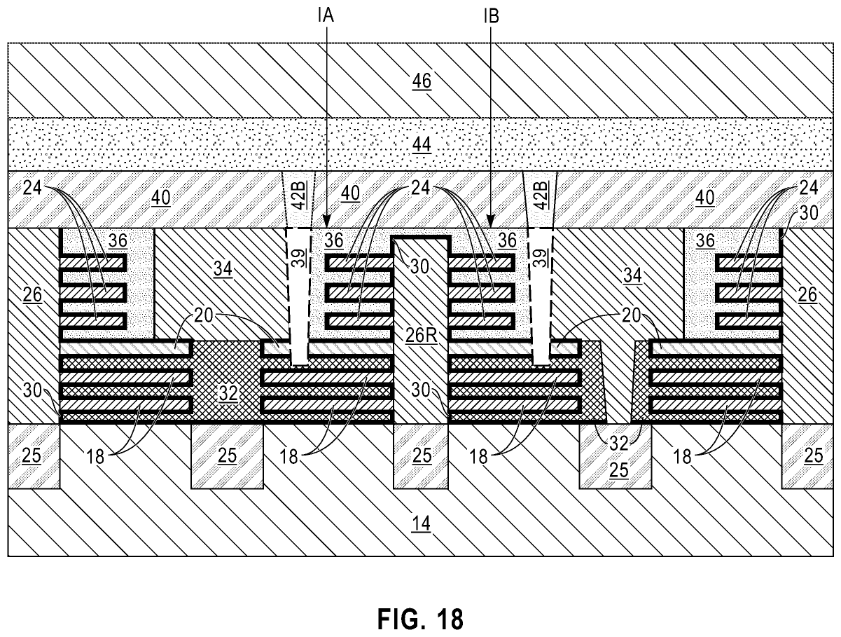

Referring now to FIG. 18, there is illustrated an exemplary semiconductor structure including a plurality of stacked forksheet transistors in accordance with a further embodiment of the present application. The illustrated structure shown in FIG. 18 is similar to the one illustrated in FIG. 15 except for the frontside wiring configuration. Although FIG. 18 illustrates the presence of a carrier wafer 46 on top of the frontside BEOL interconnect structure 44, embodiments include omitting the carrier wafer 46 from the structure.

The illustrated structures shown in FIGS. 14-18 can be derived from the processing mentioned above in regard to forming the illustrated structure shown in FIG. 13 with minor processing variations depending on whether backside processing is, or is not, performed, and the location of the frontside bottom gate contact structures and MOL contact structures. These minor process variations are apparent to one skilled in the art, and can readily derived from the processing steps employed in providing the structure illustrated in FIG. 13.

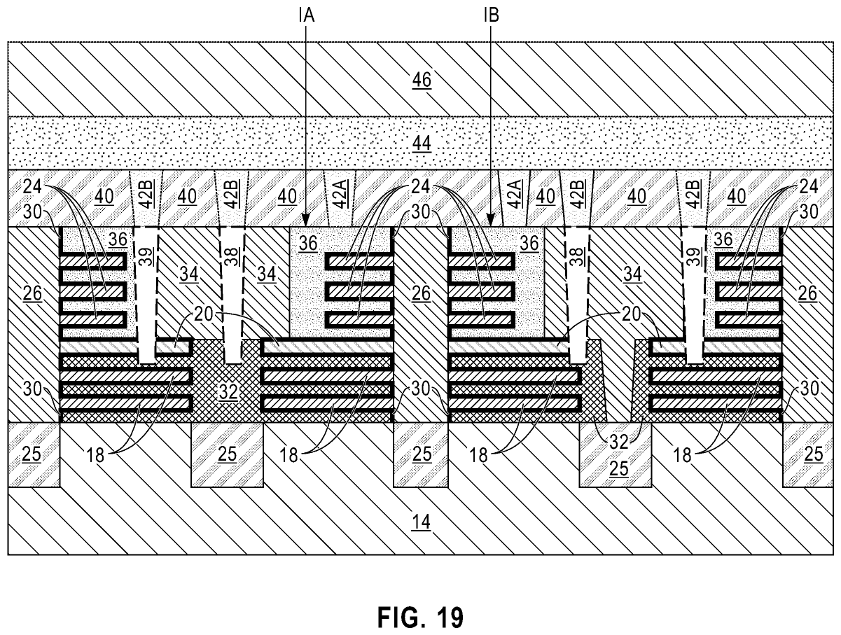

Referring now to FIG. 19, there is illustrated an exemplary semiconductor structure including a plurality of stacked forksheet transistors in accordance with a further embodiment of the present application. The structure illustrated in FIG. 19 does not include a recessed dielectric wall structure as with the structures of the other embodiments of the present application, and thus the structure illustrated in FIG. 19 does not include that shared second gate electrode between any neighboring pair of stacked forksheet transistors.

Referring back to FIGS. 13 and 15-18, there are illustrated exemplary semiconductor structures in accordance with the present application. Each of the exemplary structures illustrated in FIGS. 13 and 15-18 includes dielectric wall structure (i.e., recessed dielectric wall structure 26R) directly contacting and physically separating a first stacked transistor (i.e., stacked transistor IA shown in FIGS. 13 and 15-18) from a second stacked transistor (i.e., stacked transistor IB shown in FIGS. 13 and 15-18); merged top gate electrode (i.e., second gate electrode 36) extending over the dielectric wall structure and surrounding a top semiconductor channel region (i.e., the plurality of second semiconductor channel material nanosheets 24 located on the left hand side of recessed dielectric wall structure 26R) of the first stacked transistor and a top semiconductor channel region (i.e., the plurality of second semiconductor channel material nanosheets 24 located on the right hand side of recessed dielectric wall structure 26R) of the second stacked transistor; a bottom gate electrode (i.e., first gate electrode 32 located on the left hand side of recessed dielectric wall structure 26R) of the first stacked transistor surrounding a bottom semiconductor channel region (i.e., the plurality of first semiconductor channel material nanosheets 18 located on the left hand side of recessed dielectric wall structure 26R) of the first stacked transistor; a bottom gate electrode (i.e., second gate electrode 32 located on the right hand side of recessed dielectric wall structure 26R) of the second stacked transistor surrounding a bottom semiconductor channel region (i.e., the plurality of first semiconductor channel material nanosheets 18 located on the right hand side of recessed dielectric wall structure 26R) of the second stacked transistor; first frontside bottom gate contact structure (i.e., the shared or non-shared frontside bottom gate contact structure located on the left hand side of the recessed dielectric wall structure 26R) contacting the bottom gate electrode of the first stacked transistor (i.e., first gate electrode 32 located on the left hand side of the recessed dielectric wall structure); second frontside bottom gate contact structure (i.e., the shared or non-shared frontside bottom gate contact structure located on the right hand side of the recessed dielectric wall structure 26) contacting the bottom gate electrode (i.e., first gate electrode 32 located on the right hand side of the recessed dielectric wall structure 26R) of the second stacked transistor; and a frontside back-end-of-the-line (BEOL) interconnect structure located over the first stacked transistor and the second stacked transistor and in electrical contact with the first frontside bottom gate contact structure and the second frontside bottom gate contact structure.

In the structures illustrated in FIGS. 13 and 15-18, the stacked transistors provide improved circuit density and performance over their non-stacked counterparts. The recessed dielectric wall structure 26R illustrated in FIGS. 13 and 15-18 permits the formation of first and second stacked transistors (IA, IB) that have the merged top gate electrode (i.e., second gate electrode 36 that is located on each side of the recessed dielectric wall structure 26R and is present on top of the recessed dielectric wall structure 26R shown in each of FIGS. 13 and 15-18 is shared between the two stacked transistors). The merged top gate electrode can facilitate some circuit designs without having to route through additional BEOL connections thus reducing complexity and improving power, performance and area matrices. The merged top gate electrode can provide input gate signal for first and second stacked transistors. The structures illustrated in FIGS. 13 and 15-18 illustrate structure in which the bottom gate electrodes of each of the first and second stacked transistors is wired, i.e., electrically connected, the frontside BEOL interconnect structure 44. The electrically connection occurs through the use of the frontside bottom gate contact structures illustrated in each of FIGS. 13 and 15-18.

In some embodiment and as is shown in each of FIGS. 13 and 15-18, the bottom semiconductor channel region of the first stacked transistor and the bottom semiconductor channel region of the second stacked transistor have a first width, and the top semiconductor channel region of the first stacked transistor and the top semiconductor channel region of the second stacked transistor have a second width, wherein the second width is less than the first width. The different semiconductor channel region widths for the first and second stacked transistors can provide different driving strength (current) depending on their uses and can provide optimize device performance.

In some embodiments, and as is shown in each of FIGS. 13 and 15-18, the electrical contact of the frontside BEOL interconnect structure 44 with the first frontside bottom gate contact structure is through a first bottom gate middle-of-the-line (MOL) contact structure contact structure (i.e., the bottom gate MOL contact structure 42B shown on the left hand side of the recessed dielectric wall structure 26R), and the electrical contact of the frontside BEOL interconnect structure 44 with the second frontside bottom gate contact structure is through a second bottom gate MOL contact structure (i.e., the bottom gate MOL contact structure 42B shown on the right hand side of the recessed dielectric wall structure 26R), wherein the first bottom gate MOL contact structure and the second bottom gate MOL contact structure are embedded in MOL dielectric layer 40.

In some embodiments, and as is shown in FIGS. 13, 16 and 17, the structure can further include shared top gate MOL contact structure 42C located in the MOL dielectric layer 40 and electrically connecting the merged top gate electrode to the frontside BEOL interconnect structure 44. The shared top gate MOL contact structure 42C provides direct wiring of the merged top gate electrode to the frontside BEOL interconnect structure 44.

In some embodiments, and as is shown in FIG. 13, the first frontside bottom gate contact structure is non-shared frontside bottom gate contact structure 38, and the second frontside bottom gate contact structure is shared frontside bottom gate contact structure 39 that contacts a sidewall of the merged top gate electrode of the second stacked transistor. In FIG. 15, the orientation of the shared and non-shared frontside bottom gate contact structures are reversed as compared to that shown in FIG. 13. The use of the non-shared frontside bottom gate contact structures 38 can permit the formation of independently controlled top and bottom gate structures, while the use of shared frontside bottom gate contact structures 39 permit the formation of shared top and bottom gate structures.

In some embodiments, and as is illustrated in FIGS. 16-17, the first frontside bottom gate contact structure is a first non-shared frontside bottom gate contact structure (i.e., non-shared frontside bottom gate contact structure 38 on the left hand side of the recessed dielectric wall structure 26R), and the second frontside bottom gate contact structure is a second non-shared frontside bottom gate contact structure (i.e., non-shared frontside bottom gate contact structure 38 on the left hand side of the recessed dielectric wall structure 26R).

In some embodiments, and as is illustrated in FIGS. 16 and 17, the first frontside bottom gate contact structure is a first shared frontside bottom gate contact structure (i.e., shared frontside bottom gate contact structure 39 on the left hand side of the recessed dielectric wall structure 26R), and the second frontside bottom gate contact structure is a second shared frontside bottom gate contact structure (i.e., shared frontside bottom gate contact structure 39 on the right hand side of the recessed dielectric wall structure 26R).

In some embodiments and as is shown in FIG. 13, the structure can further include backside interconnect structure 50 located beneath the first stacked transistor and the second stacked transistor.

In some embodiments, and as is shown in FIGS. 13 and 15-18 the structure can further include frontside gate cut structure 34 located on each side of the dielectric wall structure, wherein the frontside gate cut structure 34 is adjacent to the merged top gate electrode (i.e., second electrode 36) that is present on both sides of the dielectric wall structure. The presence of the front gate cut structure 34 not only isolates the bottom gate electrode of each of the first and second stacked transistors from the top gate electrode of each of the first and second transistors, but in processing the formation of the frontside gate cut structure 34 allows one to remove the first gate electrode 32 (i.e., the bottom gate electrode) from top device area without removing or damaging the first gate electrode 32 in the bottom device area.

In some embodiments, and as is shown in FIGS. 13 and 15-18, the structure can further include backside gate cut structure 48 contacting the frontside gate cut structure 34 that is present on at least one side of the dielectric wall structure. The backside gate cut structure 48 can be used to cut the bottom gate electrode of an adjacent stacked transistor from the first and/or second stacked transistor that is in contact with the dielectric wall structure.

In some embodiments, and as is illustrated in FIG. 14, the semiconductor structure includes dielectric wall structure (i.e., recessed dielectric wall structure 26R) directly contacting and physically separating a first stacked transistor (i.e., stacked transistor IA shown in FIGS. 13 and 15-18) from a second stacked transistor (i.e., stacked transistor IB shown in FIGS. 13 and 15-18); merged top gate electrode (i.e., second gate electrode 36) extending over the dielectric wall structure and surrounding a top semiconductor channel region (i.e., the plurality of second semiconductor channel material nanosheets 24 located on the left hand side of recessed dielectric wall structure 26R) of the first stacked transistor and a top semiconductor channel region (i.e., the plurality of second semiconductor channel material nanosheets 24 located on the right hand side of recessed dielectric wall structure 26R) of the second stacked transistor; a bottom gate electrode (i.e., first gate electrode 32 located on the left hand side of recessed dielectric wall structure 26R) of the first stacked transistor surrounding a bottom semiconductor channel region (i.e., the plurality of first semiconductor channel material nanosheets 18 located on the left hand side of recessed dielectric wall structure 26R) of the first stacked transistor; a bottom gate electrode (i.e., second gate electrode 32 located on the right hand side of recessed dielectric wall structure 26R) of the second stacked transistor surrounding a bottom semiconductor channel region (i.e., the plurality of first semiconductor channel material nanosheets 18 located on the right hand side of recessed dielectric wall structure 26R) of the second stacked transistor; a first backside bottom gate contact structure (i.e., the backside bottom gate contact structure 49 located on the left hand side of the recessed dielectric wall structure 15R) contacting the bottom gate electrode of the first stacked transistor; a second backside bottom gate contact structure (i.e., the backside bottom gate contact structure 49 located on the right hand side of the recessed dielectric wall structure 15R) contacting the bottom gate electrode of the second stacked transistor; and backside interconnect structure 50 located beneath the first stacked transistor and the second stacked transistor and in electrically contact with the first backside bottom gate contact structure and the second backside bottom gate contact structure. The backside bottom gate contact structures 49 permit direct contact of the bottom gate electrode (i.e. first gate electrode 32) of each of the first and stacked stack transistors from the backside of the device. This can provide improved wiring and connection schemes helping power, performance, and area metrics. The backside bottom gate contact structures 49 can provide signal control of the gates from the backside of the structure.

In addition to the benefits mentioned above for the backside wiring, the stacked transistors illustrated in FIG. 14 provide improved circuit density and performance over their non-stacked counterparts. The recessed dielectric wall structure 26R illustrated in FIG. 14 permits the formation of first and second stacked transistors (IA, IB) that have the merged top gate electrode (i.e., second gate electrode 36 that is located on each side of the recessed dielectric wall structure 26R and is present top of the recessed dielectric wall structure 26R shown in FIG. 14 is shared between the two stacked transistors). The merged top gate electrode can facilitate some circuit designs without having to route through additional BEOL connections thus reducing complexity and improving power, performance and area matrices. The merged top gate electrode can provide input gate signal for first and second stacked transistors.

In some embodiments that include the backside bottom gate contact structures 49 and as is shown in FIG. 14, the bottom semiconductor channel region of the first stacked transistor and the bottom semiconductor channel region of the second stacked transistor have a first width, and the top semiconductor channel region of the first stacked transistor and the top semiconductor channel region of the second stacked transistor have a second width, wherein the second width is less than the first width. The different semiconductor channel region widths for the first and second stacked transistors can provide different driving strength (current) depending on their uses and can provide optimize device performance.

In some embodiments, and as is shown in FIG. 14, the structure can further include frontside BEOL interconnect structure 44 located above the first stacked transistor and the second stacked transistor. In such embodiments including the frontside BEOL interconnect structure 44, the structure illustrated in FIG. 14, can further include shared top gate MOL contact 42C structure electrically connecting the merged top gate electrode to the frontside BEOL interconnect structure 36.

In some embodiments, and as is illustrated in FIG. 14, the structure can further include frontside gate cut structure 34 located on each side of the dielectric wall structure, the frontside gate cut structure 34 is adjacent to the merged top gate electrode that is present on both sides of the dielectric wall structure. In some embodiments, and as is illustrated in FIG. 14, the structure can further include backside gate cut structure 48 contacting the frontside gate cut structure 34. The benefits provided from the frontside gate cut structure 34 and the backside gate cut structure 48 are the same as mentioned above in respect to the embodiments illustrated in FIGS. 13 and 15-18.

In some embodiments, and as illustrated in FIG. 19, the semiconductor structure includes a dielectric wall structure 26 directly contacting and physically separating a first stacked transistor IA from a second stacked transistor IB; first top gate electrode (i.e., second gate electrode 36 located on the left hand side of the dielectric wall structure 26) located on a first side the dielectric wall structure 26 and surrounding a top semiconductor channel region (i.e., the plurality of second semiconductor channel material nanosheets 24 located on the left side of the dielectric wall structure 26) of the first stacked transistor; a second top gate electrode (i.e., second gate electrode 36 located on the right hand side of the dielectric wall structure 26) located on a second side the dielectric wall structure and surrounding a top semiconductor channel region (i.e., the plurality of second semiconductor channel material nanosheets 24 located on the right side of the dielectric wall structure 26) of the second stacked transistor; a first bottom gate electrode (i.e., first gate electrode 32 located on the left hand side of the dielectric wall structure 26) surrounding a bottom semiconductor channel region (i.e., the plurality of first semiconductor channel material nanosheets 18 located on the left side of the dielectric wall structure 26) of the first stacked transistor; a second bottom gate electrode (i.e., first gate electrode 32 located on the right hand side of the dielectric wall structure 26) surrounding a bottom semiconductor channel region (i.e., the plurality of first semiconductor channel material nanosheets 18 located on the right side of the dielectric wall structure 26) of the second stacked transistor; a first non-shared backside bottom gate contact structure (i.e., non-shared backside contact structure 38 located on the left hand side of the dielectric wall structure 26) contacting the first bottom gate electrode of the first stacked transistor; a second non-shared backside bottom gate contact structure (i.e., non-shared backside contact structure 38 located on the right hand side of the dielectric wall structure 26) contacting the second bottom gate electrode of the second stacked transistor; and frontside BEOL interconnect structure 44 located over the first stacked transistor and the second stacked transistor and in electrical contact with the first non-shared frontside bottom gate structure and the second non-shared frontside bottom gate contact structure. In the structure illustrated in FIG. 19, stacked transistors can provide improved circuit density and performance over their non-stacked counterparts. The dielectric wall structure 26 illustrated in FIG. 19 provides completely isolation between the first and second stacked transistors (IA, IB).

In some embodiments, and as is illustrated in FIG. 19, the bottom semiconductor channel region of the first stacked transistor and the bottom semiconductor channel region of the second stacked transistor have a first width, and the top semiconductor channel region of the first stacked transistor and the top semiconductor channel region of the second stacked transistor have a second width, wherein the second width is less than the first width. The benefits of using the different channel widths in the structure illustrated in FIG. 19 is the same as mentioned above.

In some embodiments, and as is illustrated in FIG. 19, the electrical contact of the frontside BEOL interconnect structure 44 with the first non-shared frontside bottom gate contact structure (i.e., non-shared frontside bottom gate contact structure 38 on the left hand side of the dielectric wall structure 26) is through a first bottom gate MOL contact structure contact structure, and the electrical contact of the frontside BEOL interconnect structure with the second non-shared frontside bottom gate contact structure (i.e., non-shared frontside bottom gate contact structure 38 on the right hand side of the dielectric wall structure 26) is through a second bottom gate MOL contact structure contact structure, wherein the first bottom gate MOL contact structure and the second bottom gate MOL contact structure are embedded in MOL dielectric layer 40.

In some embodiments, and as is illustrated in FIG. 19, the structure can further include a first top gate MOL contact structure electrically connecting the first top gate electrode to the frontside BEOL interconnect structure, and a second top gate MOL contact structure electrically connecting the second top gate electrode to the frontside BEOL interconnect structure.

In some embodiments, and as is illustrated in FIG. 19, the structure can further a frontside gate cut structure 34 located on each side of the dielectric wall structure 26, wherein the frontside gate cut structure 34 located on a first side of the dielectric wall structure 26 is adjacent to the first top gate electrode and the frontside gate cut structure 34 located on a second side of the dielectric wall structure 26 is adjacent to the second top gate electrode.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a dielectric wall structure directly contacting and physically separating a first stacked transistor from a second stacked transistor;
a merged top gate electrode extending over the dielectric wall structure and surrounding a top semiconductor channel region of the first stacked transistor and a top semiconductor channel region of the second stacked transistor;
a bottom gate electrode of the first stacked transistor surrounding a bottom semiconductor channel region of the first stacked transistor;
a bottom gate electrode of the second stacked transistor surrounding a bottom semiconductor channel region of the second stacked transistor;
a first frontside bottom gate contact structure contacting the bottom gate electrode of the first stacked transistor;
a second frontside bottom gate contact structure contacting the bottom gate electrode of the second stacked transistor; and
a frontside back-end-of-the-line (BEOL) interconnect structure located over the first stacked transistor and the second stacked transistor and in electrical contact with the first frontside bottom gate contact structure and the second frontside bottom gate contact structure.

2. The semiconductor structure of claim 1, wherein the bottom semiconductor channel region of the first stacked transistor and the bottom semiconductor channel region of the second stacked transistor have a first width, and the top semiconductor channel region of the first stacked transistor and the top semiconductor channel region of the second stacked transistor have a second width, wherein the second width is less than the first width.

3. The semiconductor structure of claim 1, wherein the electrical contact of the frontside BEOL interconnect structure with the first frontside bottom gate contact structure is through a first bottom gate middle-of-the-line (MOL) contact structure contact structure, and the electrical contact of the frontside BEOL interconnect structure with the second frontside bottom gate contact structure is through a second bottom gate MOL contact structure contact structure, wherein the first bottom gate MOL contact structure and the second bottom gate MOL contact structure are embedded in a MOL dielectric layer.

4. The semiconductor structure of claim 3, further comprising a shared top gate MOL contact structure located in the MOL dielectric layer and electrically connecting the merged top gate electrode to the frontside BEOL interconnect structure.

5. The semiconductor structure of claim 1, wherein the first frontside bottom gate contact structure is a non-shared frontside bottom gate contact structure, and the second frontside bottom gate contact structure is a shared frontside bottom gate contact structure.

6. The semiconductor structure of claim 1, wherein the first frontside bottom gate contact structure is a first non-shared frontside bottom gate contact structure, and the second frontside bottom gate contact structure is a second non-shared frontside bottom gate contact structure.

7. The semiconductor structure of claim 1, wherein the first frontside bottom gate contact structure is a first shared frontside bottom gate contact structure, and the second frontside bottom gate contact structure is a second shared frontside bottom gate contact structure.

8. The semiconductor structure of claim 1, further comprising a backside interconnect structure located beneath the first stacked transistor and the second stacked transistor.

9. The semiconductor structure of claim 1, further comprising a frontside gate cut structure located on each side of the dielectric wall structure, wherein the frontside gate cut structure is adjacent to the merged top gate electrode that is present on both sides of the dielectric wall structure.

10. The semiconductor structure of claim 9, further comprising a backside gate cut structure contacting the frontside gate cut structure that is present on at least one side of the dielectric wall structure.

11. A semiconductor structure comprising:
a dielectric wall structure directly contacting and physically separating a first stacked transistor from a second stacked transistor;
a merged top gate electrode extending over the dielectric wall structure and surrounding a top semiconductor channel region of the first stacked transistor and a top semiconductor channel region of the second stacked transistor;
a bottom gate electrode of the first stacked transistor surrounding a bottom semiconductor channel region of the first stacked transistor;
a bottom gate electrode of the second stacked transistor surrounding a bottom semiconductor channel region of the second stacked transistor;
a first backside bottom gate contact structure contacting the bottom gate electrode of the first stacked transistor;
a second backside bottom gate contact structure contacting the bottom gate electrode of the second stacked transistor; and
a backside interconnect structure located beneath the first stacked transistor and the second stacked transistor and in electrically contact with the first backside bottom gate contact structure and the second backside bottom gate contact structure.

12. The semiconductor structure of claim 11, wherein the bottom semiconductor channel region of the first stacked transistor and the bottom semiconductor channel region of the second stacked transistor have a first width, and the top semiconductor channel region of the first stacked transistor and the top semiconductor channel region of the second stacked transistor have a second width, wherein the second width is less than the first width.

13. The semiconductor structure of claim 11, further comprising a frontside BEOL interconnect structure located above the first stacked transistor and the second stacked transistor; and a shared top gate middle-of-the-line (MOL) contact structure electrically connecting the merged top gate electrode to the frontside BEOL interconnect structure.

14. The semiconductor structure of claim 11, further comprising a frontside gate cut structure located on each side of the dielectric wall structure, wherein the frontside gate cut structure is adjacent to the merged top gate electrode that is present on both sides of the dielectric wall structure.

15. The semiconductor structure of claim 14, further comprising a backside gate cut structure contacting the frontside gate cut structure.

16. A semiconductor structure comprising:
a dielectric wall structure directly contacting and physically separating a first stacked transistor from a second stacked transistor;
a first top gate electrode located on a first side the dielectric wall structure and surrounding a top semiconductor channel region of the first stacked transistor;
a second top gate electrode located on a second side the dielectric wall structure and surrounding a top semiconductor channel region of the second stacked transistor;
a first bottom gate electrode surrounding a bottom semiconductor channel region of the first stacked transistor;
a second bottom gate electrode surrounding a bottom semiconductor channel region of the second stacked transistor;
a first non-shared backside bottom gate contact structure contacting the bottom gate electrode of the first stacked transistor;
a second non-shared backside bottom gate contact structure contacting the bottom gate electrode of the second stacked transistor; and
a frontside back-end-of-the-line (BEOL) interconnect structure located over the first stacked transistor and the second stacked transistor and in electrical contact with the first non-shared frontside bottom gate contact structure and the second non-shared frontside bottom gate contact structure.

17. The semiconductor structure of claim 16, wherein the bottom semiconductor channel region of the first stacked transistor and the bottom semiconductor channel region of the second stacked transistor have a first width, and the top semiconductor channel region of the first stacked transistor and the top semiconductor channel region of the second stacked transistor have a second width, wherein the second width is less than the first width.

18. The semiconductor structure of claim 16, wherein the electrical contact of the frontside BEOL interconnect structure with the first non-shared frontside bottom gate contact structure is through a first bottom gate middle-of-the-line (MOL) contact structure contact structure, and the electrical contact of the frontside BEOL interconnect structure with the second non-shared frontside bottom gate contact structure is through a second bottom gate MOL contact structure contact structure, wherein the first bottom gate MOL contact structure and the second bottom gate MOL contact structure are embedded in a MOL dielectric layer.

19. The semiconductor structure of claim 18, further comprising a first top gate MOL contact structure electrically connecting the first top gate electrode to the frontside BEOL interconnect structure, and a second top gate MOL contact structure electrically connecting the second non top gate electrode to the frontside BEOL interconnect structure.

20. The semiconductor structure of claim 16, further comprising a frontside gate cut structure located on each side of the dielectric wall structure, wherein the frontside gate cut structure located on a first side of the dielectric wall structure is adjacent to the first top gate electrode and the frontside gate cut structure located on a second side of the dielectric wall structure is adjacent to the second top gate electrode.
